(19) United States
(12) Patent Application Publication
(10) Pub. No.: US 2026/0354042 A1
(43) Pub. Date: Nov. 5, 2026

(54) RESISTIVE SWITCHING STRUCTURE TO IMPROVE RRAM

(71) Applicant: Taiwan Semiconductor Manufacturing Company, Ltd., Hsinchu (TW)

(72) Inventors: Fa-Shen Jiang, Taoyuan City (TW); Bi-Shen Lee, Hsinchu (TW); Yi-Yang Wei, Hsinchu (TW); Chih-Ming Chen, Hsinchu City (TW); Chung-Yi Yu, Hsin-Chu (TW); Cheng-Yuan Tsai, Chu-Pei City (TW)

(21) Appl. No.: 19/742,271

(22) Filed: Jul. 15, 2026

Related U.S. Application Data
(63) Continuation of application No. 19/010,546, filed on Jan. 6, 2025.
(60) Provisional application No. 63/690,347, filed on Sep. 4, 2024.

(51) Int. Cl. H10N 70/20; H10B 63/00; H10N 70/00

(52) U.S. Cl. CPC H10N 70/24; H10B 63/30; H10N 70/023; H10N 70/063; H10N 70/066; H10N 70/841

(57) ABSTRACT

The problem of reducing forming voltage in an RRAM cell is solved by a resistive switching structure having at least two distinct layers of distinct metal oxides. Thicknesses and compositions of the layers are selected so that a difference in oxygen affinity between the layers produces intrinsic oxygen vacancies in one of the layers. The problem of increasing endurance is solved by adding a dopant metal to the lower oxygen affinity layer. The dopant metal has a higher oxygen affinity than the bulk metal of the lower oxygen affinity layer. The lower oxygen affinity layer may have a laminate structure in which the dopant metal is disposed in distinct strata. The dopant metal may have a concentration gradient within the lower oxygen affinity layer. Having the dopant metal concentration diminish in the direction of the higher oxygen affinity layer can further lower the forming.

### CROSS-REFERENCE TO RELATED APPLICATIONS

This Application is a Continuation of U.S. Application number 19/010,546, filed on Jan. 6, 2025, which claims the benefit of U.S. Provisional Application number 63/690,347, filed on Sep. 4, 2024. The contents of the above-referenced Patent Applications are hereby incorporated by reference in their entirety.

### BACKGROUND

Many modern electronic devices contain electronic memory configured to store data. Electronic memory may be volatile or non-volatile. Volatile memory stores data while it is powered, while non-volatile memory is able to keep data when power is off. Resistive random-access memory (RRAM) is one promising candidate for next generation non-volatile memory due to its simple structure and compatibility with complementary metal-oxide semiconductor (CMOS) processes. An RRAM cell includes a resistive switching structure having a variable resistance. The resistive switching structure is generally placed between two electrodes disposed within a metal interconnect structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated chip having a resistive random-access memory (RRAM) cell according to an embodiment of the present disclosure.

FIGS. 2A-2B illustrate cross-sectional views of resistive random-access memory (RRAM) cells having resistive switching structures according to various embodiments of the present disclosure.

FIGS. 3-8 illustrate cross-sectional views of integrated chips having resistive random-access memory (RRAM) cells having resistive switching structures in accordance with various embodiments of the present disclosure.

FIG. 9 illustrates a cross-sectional view of an integrated chip having a flash memory cell according to an embodiment of the present disclosure.

FIG. 10A illustrates a cross-sectional view of an integrated chip having a three-dimensional (3D) array of RRAM cells having resistive switching structures according to some embodiments of the present disclosure.

FIG. 10B provides a cut-away perspective view of one of the RRAM cells in the integrated chip of FIG. 10A.

FIG. 10C provides a plan view of the integrated chip of FIG. 10A in accordance with some embodiments.

FIGS. 11-16 illustrate cross-sectional views of an integrated chip including an RRAM cell undergoing manufacturing in accordance with some embodiments of a method of the present disclosure.

FIGS. 17-23 illustrate cross-sectional views of an integrated chip including an RRAM cell undergoing manufacturing in accordance with some embodiments of another method of the present disclosure.

FIGS. 24-27 illustrate cross-sectional views of an integrated chip including a flash memory cell undergoing manufacturing in accordance with some embodiments of a method of the present disclosure.

FIGS. 28-32 illustrate cross-sectional views of an integrated chip including a 3D array of RRAM cells undergoing manufacturing in accordance with some embodiments of a method of the present disclosure.

FIG. 33 provides a flowchart illustrating some embodiments of a method of forming an RRAM cell comprising a resistive switching structure according to the present disclosure.

FIG. 34-36 provide flowchart of methods of forming integrated chips in accordance with various embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated chips may include resistive random-access memory (RRAM) cells which have a resistive switching structure disposed between a top electrode and a bottom electrode. Current pulses may be used to reversibly switch the resistive switching structure between a high resistance state (HRS) and a low resistance state (LRS). The distinction between the HRS and the LRS may encode data and may be detected in a read operation. The read operation may be carried out at lower voltages than those used for programming the HRS and the LRS so that the state of the RRAM cell may be detected without altering the state of the RRAM cell.

Before an RRAM cell is used to store data, an initial conductive filament is typically formed across the resistive switching structure. Formation of the initial conductive filament makes subsequent write operations (that form the conductive filament) easier to perform. The initial conductive filament is formed by pulsing a forming voltage across the top and bottom electrodes.

In some types of RRAM cells, the resistive switching structure comprises metal oxides and the conductive filament is formed by oxygen vacancies in the metal oxide structure. In those types of RRAM cells, the forming voltage may break metal oxide bonds and free oxygen ions. The freed oxygen ions migrate toward the top electrode, where some of the oxygen ions may be absorbed. The migrating oxygen ions leave behind oxygen vacancies. New oxygen vacancies form more easily next to pre-existing oxygen vacancies, so the oxygen vacancies tend to align to form a conductive filament that extends along a continuous path through the resistive switching structure.

After the initial conductive filament is formed, the RRAM cell may be switched between the HRS and the LRS using voltages lower than the forming voltage. In a reset operation, the oxygen ions are driven to return to approximately their original positions so that the conductive filament is no longer operative. During a set operation the oxygen ions are again driven toward and into the top electrode so that the conductive filament is reestablished.

As transistors are made smaller, their safe operating voltages are reduced. Accordingly, the drive toward increasing integrated circuit device density has resulted in a long felt need to reduce the forming voltages for RRAM cells. One approach to reducing forming voltages is to reduce a thickness of the resistive switching structure, however, as the resistive switching structure becomes very thin (e.g., below 10 angstroms), there is a tendency for leakage currents to become excessive. In addition, as the resistive switching structure becomes thinner there is an increasing tendency for oxygen ions to spontaneously diffuse from the top electrode back into the resistive switching structure. That tendency may adversely affect the reliability of the RRAM cell.

According to some aspects of the present disclosure, an RRAM cell has a resistive switching structure that lowers the forming voltage (e.g., to about 2.3V or less) without having to thin the resistive switching structure. The resistive switching structure has two metal oxide layers that differ in the oxygen affinities of their metals. The lower oxygen affinity layer is proximate a first electrode and the higher oxygen affinity layer is proximate a second electrode. The second electrode is the one in which oxygen ions dissolve when the conductive filament is formed. In the examples of the present disclosure, the second electrode is often referred to as the top electrode, but that is merely a convention to simplify the description: the bottom electrode may be the one that is designed to have high oxygen ion solubility. The difference in oxygen affinities causes some oxygen ions to spontaneously migrate from the lower oxygen affinity layer to the higher oxygen affinity layer and thereby create intrinsic oxygen vacancies in the lower oxygen affinity layer. If the difference in oxygen affinities is sufficiently large and the thicknesses of the lower and higher oxygen affinity layers are suitably selected, the forming voltage will be lowered.

One measure of the oxygen affinity of a metal is the standard Gibbs free energy of oxygen vacancy formation for a maximum oxide (the oxide with the highest proportion of oxygen) of the metal. A higher standard Gibbs free energy of oxygen vacancy formation indicates greater oxygen affinity. Another and practically equivalent measure is the standard Gibbs free energy of formation of the maximum oxide on a per mole oxygen basis. A lower (more negative) standard Gibbs free energy of metal oxide formation indicates greater oxygen affinity. In some embodiments, a difference in standard Gibbs free energy of metal oxide formation of a first metal, which is the metal of the lower oxygen affinity layer, and the standard Gibbs free energy of metal oxide formation of a second metal, which is the metal of the higher oxygen affinity layer, is at least about 100 kJ/mol oxygen (O₂). In some embodiments, the difference is at least about 200 kJ/mol oxygen (O₂).

In some embodiments, a ratio of thicknesses between the lower oxygen affinity layer and the higher oxygen affinity layer is in the range from about 0.5 to about 1.3. In some embodiments, the thicknesses ratio is in the range from about 0.8 to about 1.0. In some embodiments, a thickness of the resistive switching structure is in the range from about 20 angstroms to about 45 angstroms. In some embodiments, each of the lower oxygen affinity layer and the higher oxygen affinity layer has a thickness of at least about 10 angstroms. If the higher oxygen affinity layer is too thin, or too thin relative to the lower oxygen affinity layer, it may not have the capacity to create a sufficient number of oxygen vacancies in the lower oxygen affinity layer to appreciably lower the forming voltage. If the higher oxygen affinity layer is too thick, it may increase the forming voltage. If the lower oxygen affinity layer is too thin, it may not be able to hold enough oxygen vacancies to appreciably lower the forming voltage. If the lower oxygen affinity layer and the higher oxygen affinity layer combined are too thin, leakage currents may be excessive.

Another consideration for RRAM is endurance. Endurance refers to the ability of a large number of RRAM cells to perform reliably over the lifetime of an integrated chip. A typical endurance test compares the performance of a large number or RRAM cells (e.g., 500,000) before and after 10,000 program and reset operation in combination with baking. The read currents in the HRS and the LRS exhibit Gaussian-type distributions among the RRAM cells. A memory device passes the endurance test if even after the test there is no overlap for a particular read voltage between the range of read currents among the RRAM cells when they are in the HRS and the range of read currents among the RRAM cells when they are in the LRS. It has been observed that a memory device composed of RRAM cells having the lower oxygen affinity layer and the higher oxygen affinity layer may fail the endurance test if the baking conditions are severe, e.g., 200 °C for an extended period. The inventors have determined that this failure is primarily due to progressively increasing dispersion of oxygen vacancies in the lower oxygen affinity layer, which is manifest in part by the conductive filament passing through the lower oxygen affinity layer becoming progressively wider. As the oxygen vacancies become more widely dispersed, it may become difficult to fill all the oxygen vacancies with oxygen ions during a reset operation.

According to some aspects of the present disclosure, the endurance problem is solved by adding to the lower oxygen affinity layer a suitable amount of a third metal, which has a higher oxygen affinity than the first metal. The third metal may be referred to as a dopant because its concentration in the lower oxygen affinity layer is relatively small in comparison to the first metal. The third metal inhibits the spread of oxygen vacancies in the lower oxygen affinity layer without significantly increasing the forming voltage. In some embodiments, from about 0.1% to about 10% of the atoms in the lower oxygen affinity layer are the third metal. In some embodiments, from about 0.5% to about 4% of the atoms in the lower oxygen affinity layer are the third metal. In some embodiments, there are at least five times as many atoms of the first metal as atoms of the third metal in the lower oxygen affinity layer. If the concentration of the third metal is too low, it may not be effective in reducing the dispersion of oxygen vacancies. If the concentration of the third metal is too high, it may increase the forming voltage excessively.

In some embodiments, a difference in oxygen affinity between the first metal (the bulk metal in the lower oxygen affinity layer) and the third metal (the dopant metal in the lower oxygen affinity layer) is at least about 100 kJ/mol oxygen (O₂). In some embodiments, the difference in oxygen affinity between the bulk metal and the dopant metal is at least about 200 kJ/mol oxygen (O₂). In some embodiments, the dopant metal has a lower oxygen affinity than the metal of the higher oxygen affinity layer (the second metal). If the oxygen affinity of the dopant metal is too low, it may not be effective in reducing the dispersion of oxygen vacancies. If the oxygen affinity of the dopant metal is too high, it may inhibit the formation or intrinsic oxygen vacancies or otherwise increase the forming voltage excessively.

In some embodiments, the higher oxygen affinity layer is or comprises zirconium oxide (ZrO). In some of these embodiments, the lower oxygen affinity layer is or comprises hafnium tantalum oxide (HfTaO), aluminum tantalum oxide (AlTaO), lanthanum tantalum oxide (LaTaO), titanium tantalum oxide (TiTaO), titanium silicon oxide (TiSiO), hafnium silicon oxide (HfSiO), or hafnium zinc oxide (HfZnO). These particular combinations of lower oxygen affinity layer bulk/dopant metal oxide are particularly well suited in conjunction with a zirconium oxide (ZrO) higher oxygen affinity layer for providing an RRAM switching structure that has a low forming voltage associated with forming intrinsic oxygen vacancies and a high endurance associated with inhibiting formation of dispersed oxygen vacancies.

In some embodiments, the higher oxygen affinity layer is or comprises hafnium oxide (HfO). In some of these embodiments, the lower oxygen affinity layer is or comprises zirconium tantalum oxide (ZrTaO), lanthanum tantalum oxide (LaTaO), titanium tantalum oxide (TiTaO), zirconium silicon oxide (ZrSiO), or zirconium zinc oxide (ZrZnO). These particular combinations of low oxygen affinity metal/dopant metal oxide are particularly well suited in conjunction with a hafnium oxide (HfO) higher oxygen affinity layer for providing an RRAM switching structure that has a low forming voltage associated with forming intrinsic oxygen vacancies and a high endurance associated with inhibiting formation of dispersed oxygen vacancies.

In some embodiments, the higher oxygen affinity layer is or comprises lanthanum oxide (LaO). In some of these embodiments, the lower oxygen affinity layer is or comprises hafnium tantalum oxide (HfTaO), aluminum tantalum oxide (AlTaO), hafnium silicon oxide (HfSiO), hafnium zinc oxide (HfZnO), or zirconium zinc oxide (ZrZnO). These particular combinations of low oxygen affinity metal/dopant metal oxide are particularly well suited in conjunction with a lanthanum oxide (LaO) higher oxygen affinity layer for providing an RRAM switching structure that has a low forming voltage associated with forming intrinsic oxygen vacancies and a high endurance associated with inhibiting formation of dispersed oxygen vacancies.

For purposes of the present disclosure, including determining which is the bulk metal and which is the dopant metal in the foregoing embodiments, the following standard Gibbs free energies of oxide formation expressed in kJ/mol oxygen (O₂) may be used: ruthenium (Ru, -274), zinc (Zn, -640), tantalum (Ta, -750), silicon (Si, -860), titanium (Ti, -889), hafnium (Hf, -1000), aluminum (Al, -1055), zirconium (Zr, -1100), lanthanum (La, -1140), neodymium (Nd, -1150), gadolinium (Gd, -1160), yttrium (Y, -1270).

In some embodiments, the lower oxygen affinity switching layer is formed by atomic layer deposition (ALD). In some embodiments, the dopant metal oxide is deposited in separate cycles from the bulk metal oxide. It has been found that the lower oxygen affinity switching layer performs better if the dopant metal is deposited in separate cycles as opposed to if the dopant metal precursor is combined with the bulk metal precursor so that both metal oxides deposit simultaneously. In some embodiments, a ratio of bulk metal oxide to dopant metal oxide deposition cycles is in the range from 3:1 to 15:1. In some embodiments, a ratio of bulk metal oxide to dopant metal oxide deposition cycles is in the range 5:1 to 10:1. In some embodiments, a ratio of bulk metal oxide to dopant metal oxide deposition cycles is at least 6:1. If the ratio is too low, the forming voltage may increase. If the ratio is too high, there may not be enough dopant metal to improve endurance.

It should be appreciated that the proportion of bulk metal atoms to dopant metal atoms in the lower oxygen affinity switching layer may not be the same as the ratio of deposition cycles: fewer dopant metal atoms may deposit per cycle than bulk metal atoms. The dopant deposition amount per cycle may be affected by crystal structure and may be controlled within an upper limit by varying the deposition conditions. In some embodiments, conditions are selected to avoid saturating the surface during dopant deposition cycles.

Although the dopant metal oxide may not form a complete monolayer during a dopant deposition cycle, the bulk metal oxide generally deposits in complete monolayers. Accordingly, between adjacent dopant-containing strata in the lower oxygen affinity switching layer are a plurality of monolayers of the bulk metal oxide approximately equal to the number bulk metal oxide deposition cycles per dopant metal oxide deposition cycle. Thus, in some embodiments there are from about 3 to about 15 monolayers of bulk metal oxide between adjacent dopant-containing strata in the lower oxygen affinity switching layer. In some embodiments there are from about 5 to about 10 monolayers of bulk metal oxide between adjacent dopant-containing strata. In some embodiments, there are three or more dopant-containing strata in the lower oxygen affinity switching layer so that the pattern is repeated at least once. The thickness of a monolayer of the bulk metal oxide may be determined, e.g., from the density of the bulk metal oxide, and the number of monolayers between adjacent dopant-containing strata may then be determined from the distance between the dopant-containing strata. The effectiveness of the dopant for improving endurance has been experimentally confirmed for the case in which the dopant metal is distributed as described in this paragraph.

The inventors observed that the dopant in the lower oxygen affinity switching layer narrows the conductive filament in the lower oxygen affinity without increasing the forming voltage. From the narrowness of the conductive filament, the inventors speculated and then confirmed that the forming voltage could be further reduced. In particular, and in accordance with another aspect of the present disclosure, the forming voltage is further reduced without increasing leakage or reducing endurance by providing the lower oxygen affinity switching layer with a graded concentration of the dopant. The grading is such that the dopant metal concentration decreases in the direction of the higher oxygen affinity layer.

The width of the conductive filament tends to expand from the bottom electrode to the top electrode. As the dopant metal concentration diminishes, the expansion rate increases. Where the expansion rate is higher, oxygen vacancy formation occurs more easily. By keeping the higher dopant metal concentration proximate the bottom electrode, the formation of dispersed oxygen vacancies that cannot easily be filled during the reset operation is suppressed. By allowing the dopant metal concentration to diminish toward the top electrode, the forming voltage is reduced without leading to excess oxygen vacancies. In some embodiments, the forming voltage is reduced to 2.1 V or less. In some embodiments, the forming voltage is reduced to 2.0 V or less. In some embodiments, the forming voltage is reduced to below 2.0 V.

In some embodiments, the lower oxygen affinity switching layer includes two sublayers having different dopant metal concentrations. In some embodiments, the lower dopant metal concentration sublayer has from about 50% to about 80% the dopant metal concentration in the higher dopant metal concentration sublayer. In some embodiments, the lower oxygen affinity switching layer includes three sublayers having dopant metal concentrations that diminish in the direction of the higher oxygen affinity layer and the top electrode. In some embodiments, the lowest dopant metal concentration sublayer has from about 40% to about 80% the dopant metal concentration in the highest dopant metal concentration sublayer. In some embodiments, the lowest dopant metal concentration sublayer has from about 50% to about 80% the dopant metal concentration in the highest dopant metal concentration sublayer. In some embodiments, the intermediate dopant metal concentration sublayer has from about 70% to about 95% the dopant metal concentration in the highest dopant metal concentration sublayer. In some embodiments, the intermediate dopant metal concentration sublayer has from about 80% to about 90% the dopant metal concentration in the highest dopant metal concentration sublayer. If the dopant metal concentrations are diminished too greatly in comparison to the highest dopant metal concentration sublayer, the endurance of the RRAM cell may be reduced excessively. If the dopant metal concentrations are diminished too little, the reduction in forming voltage may not be realized.

In some embodiments, a lower oxygen affinity layer with a graded dopant metal concentration is formed by atomic layer deposition in which the dopant metal oxide is deposited in separate cycles from the bulk metal oxide. In some embodiments, increasing numbers of bulk metal oxide deposition cycles are carried out between successive dopant metal oxide deposition cycles. In some embodiments, a number of bulk metal oxide deposition cycles is increased by one from the number between a first and a second dopant metal oxide deposition cycle and the number between the second and a third dopant metal oxide deposition cycle. In some embodiments, the number is increased by two. In some embodiments, the number of bulk metal oxide deposition cycles between successive dopant metal oxide deposition cycles assumes three or more distinct values over the course of forming the lower oxygen affinity switching layer (e.g., a first dopant metal oxide deposition cycle, 6 bulk metal oxide deposition cycles, a second dopant metal oxide deposition cycle, 8 bulk metal oxide deposition cycles, a third dopant metal oxide deposition cycle, 9 bulk metal oxide deposition cycles, and then a fourth dopant metal oxide deposition cycle). The dopant metal within the lower oxygen affinity switching layer may be concentrated in strata that are spaced apart by numbers of monolayers of the bulk metal oxide approximately equaling the numbers of bulk metal oxide deposition cycles between dopant metal oxide deposition cycles.

An RRAM cell according to the present disclosure may be set to the LRS and reset to the HRS by applying suitable voltages for suitable periods to the top electrode and the bottom electrode. In principle, reset can be either unipolar or bipolar. In bipolar reset, the current for the reset operation is in the opposite direction as compared to the set operation. In some embodiments of a process of operating a memory cell according to the present disclosure, the reset is bipolar. It has been found that RRAM cells according to the present disclosure are less susceptible to overshoot currents that may slowly damage the resistive switching structure, thereby reducing endurance, if bipolar reset is consistently employed.

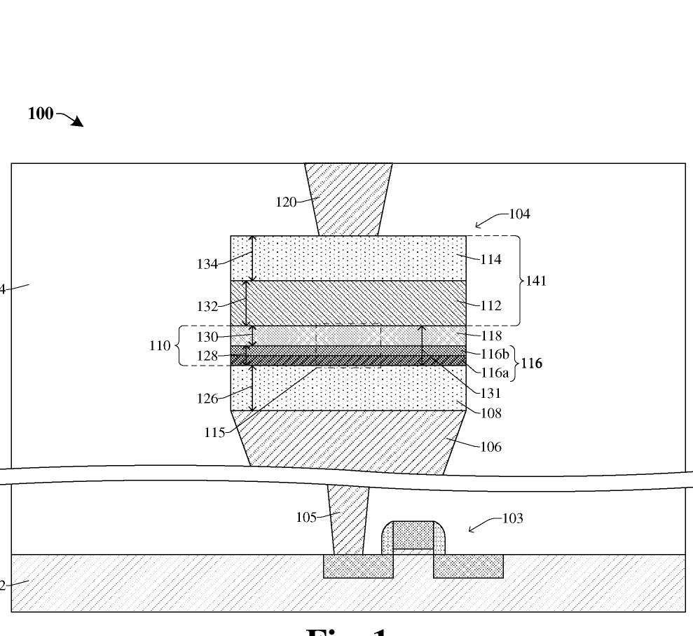

FIG. 1 illustrates a cross-sectional view of an integrated chip 100 that including a resistive random-access memory (RRAM) cell 104 that has a resistive switching structure 110 according to some embodiments. The resistive switching structure 110 includes a lower oxygen affinity switching layer 116 proximate a bottom electrode 108 and a higher oxygen affinity switching layer 118 proximate a top electrode 141. The lower oxygen affinity switching layer 116 include a first sublayer 116a and a second sublayer 116b. Both the first sublayer 116a and the second sublayer 116b include a dopant metal. The first sublayer 116a has a higher concentration of the dopant metal than the second sublayer 116b.

The RRAM cell 104 is disposed over a substrate 102. A transistor 103 disposed on the substrate 102 may provide an access control device for the RRAM cell 104. In some embodiments, the transistor 103 is a metal-oxide-semiconductor field-effect transistor (MOSFET) or some other suitable transistor. In various embodiments, the transistor 103 may be configured to supply and/or facilitate supplying suitable bias conditions to the RRAM cell 104, such that the RRAM cell 104 may be switched between an LRS and an HRS.

A dielectric structure 124 comprising one or more dielectric materials overlies the substrate 102. The RRAM cell 104 is disposed within the dielectric structure 124. One or more conductive structures disposed within the dielectric structure 124 may be configured to electrically couple the transistor 103 to the RRAM cell 104. For example, the transistor 103 may be electrically coupled to the RRAM cell 104 by way of a lower via 105 and a lower conductive wire 106. An upper conductive structure 120 disposed within the dielectric structure 124 over the RRAM cell 104 provides a second contact for the RRAM cell 104.

The lower oxygen affinity switching layer 116 and the higher oxygen affinity switching layer 118 comprise metal oxides. In some embodiments, the higher oxygen affinity switching layer 118 is or comprises an oxide of a metal having a standard Gibbs free energy of oxide formation of -1000 kJ/mol O₂ or lower. In some embodiments, the higher oxygen affinity switching layer 118 is or comprises one of zirconium oxide (ZrO), lanthanum oxide (LaO), hafnium oxide (HfO), gadolinium oxide (GdO), yttrium oxide (YO), or the like. In some embodiments, the higher oxygen affinity switching layer 118 has a thickness 130 in the range from about 10 angstroms to about 25 angstroms.

In some embodiments, the lower oxygen affinity switching layer 116 comprises an oxide of a metal having a standard Gibbs free energy of oxide formation of about -900 kJ/mol O2 or higher. In some embodiments, the lower oxygen affinity switching layer 116 comprises an oxide of a metal having a standard Gibbs free energy of oxide formation in the range from about -750 kJ/mol O2 (that of tantalum) to about -500 kJ/mol O2. If the oxygen affinity of the lower oxygen affinity switching layer 116 is too high, than it may not be possible to form intrinsic oxygen vacancies and lower the forming voltage. If the oxygen affinity of the lower oxygen affinity switching layer 116 is too low, than leakage current may become excessive. In some embodiments, the lower oxygen affinity switching layer 116 comprises one of zinc oxide (ZnO), tantalum oxide (TaO), silicon oxide (SiO), germanium oxide (GeO), indium tin oxide (ITO), indium gallium zinc oxide (IGZO), ruthenium oxide (RuO), or the like. Indium tin oxide (ITO) has a standard Gibbs free energy of formation of about -550 kJ/mol O2. Indium gallium zinc oxide (IGZO) has a standard Gibbs free energy of formation of about -620 kJ/mol O2.

In some embodiments, the lower oxygen affinity switching layer 116 has a thickness 128 in the range from about 10 angstroms to about 25 angstroms. The difference in oxygen affinity between the lower oxygen affinity switching layer 116 and the higher oxygen affinity switching layer 118 is sufficient to cause oxygen ions to spontaneously migrate from the lower oxygen affinity switching layer 116 to the higher oxygen affinity switching layer 118, creating intrinsic oxygen vacancies in the lower oxygen affinity switching layer 116 to an extent that reduces a forming voltage for the RRAM cell 104.

The number of intrinsic oxygen vacancies in the lower oxygen affinity switching layer 116 depends on the relative thicknesses of the higher oxygen affinity switching layer 118. In some embodiments, a ratio of the thickness 130 of the higher oxygen affinity switching layer 118 to the thickness 128 of the lower oxygen affinity switching layer 116 is 0.85 or greater. In some embodiments, the ratio is 1:1 or greater. These ratios provide the higher oxygen affinity switching layer 118 with the capacity to receive a sufficient number of oxygen ions from the lower oxygen affinity switching layer 116 and create a sufficient number of oxygen vacancies to realize the desired reduction in forming voltage.

The lower oxygen affinity switching layer 116 further comprises a dopant metal oxide. The metal having the higher concentration in the lower oxygen affinity switching layer 116 is referred to as the bulk metal. The concentration of the dopant metal may be sufficiently low that the overall oxygen affinity of the lower oxygen affinity switching layer 116 is not substantially altered by the dopant metal. The dopant metal has a higher oxygen affinity than the bulk metal. In some embodiments, the dopant metal has a standard Gibbs free energy of oxide formation of less than about -750 kJ/mol O₂ (less than that of tantalum). The dopant metal increases the endurance of the RRAM cell 104.

The dopant metal may be distributed through the lower oxygen affinity switching layer 116. In some embodiments, the distribution includes a concentration gradient so that an upper portion of the lower oxygen affinity switching layer 116, which is the sublayer 116b, has a distinct concentration of the dopant metal from a lower portion of the lower oxygen affinity switching layer 116, which is the sublayer 116a. The concentration gradient is such that the dopant metal concentration decreases in the direction of the higher oxygen affinity switching layer 118.

The distinction between the sublayer 116a and the sublayer 116b may be made on the basis of distance from the bottom electrode 108. In other words, there need not be an abrupt transition between the sublayer 116a and the sublayer 116b for these to be considered distinct sublayers. Concentrations within the sublayers 116a and 116b maybe be determined based on overall content in the sublayer divided by volume of the sublayer.

The sublayers 116a and 116b may have similar thicknesses. In some embodiments, the thinner of the sublayers 116a and 116b is at least 50% a thickness of the thickest of the sublayers 116a and 116b. In some embodiments, the sublayers 116a and 116b have the same thickness.

In some embodiments, the lower oxygen affinity switching layer 116 has a sub-stoichiometric amount of oxygen with respect to the maximum oxides of its metal constituents. In some embodiments, the oxygen amount is in the range from about 80 to about 99.5% of the stoichiometric amount. In some embodiments, the oxygen amount is in the range from about 90 to about 95% of the stoichiometric amount. A sub-stoichiometric amount of oxygen lowers the forming voltage. If the oxygen amount is too high, the forming voltage may be too high. If the oxygen amount is too low, leakage currents may be excessive.

In some embodiments, the sublayer 116a and the sublayer 116b each have a dopant concentration in the range from 0.1% to about 10% on an atomic basis. If the dopant amount is too low, the benefit of improved endurance may not be realized. If the dopant amount is too high, the forming voltage may increase excessively. In some embodiments, the sublayer 116b has from about 50% to about 80% the dopant metal concentration of the sublayer 116a. In some embodiments, the dopant metal concentration of the sublayer 116a is 20% or less than a bulk metal concentration in the sublayer 116a.

In some embodiments, the higher oxygen affinity switching layer 118 has a sub-stoichiometric amount of oxygen with respect to the maximum oxides of its metal constituents. In some embodiments, the oxygen amount is in the range from about 80 to about 99.5% of the stoichiometric amount. In some embodiments, the oxygen amount is in the range from about 90 to about 95% of the stoichiometric amount. A sub-stoichiometric amount of oxygen in the higher oxygen affinity switching layer 118 also contributes to realizing a lower forming voltage. If the oxygen amount in the higher oxygen affinity switching layer 118 is too high, the forming voltage may be too high. If the oxygen amount in the higher oxygen affinity switching layer 118 is too low, leakage currents may be excessive.

The initial conductive filament comprises oxygen vacancies that are disposed within a region 115 and extend from a top surface of the bottom electrode 108 to a bottom surface of the capping structure 112. Typically, forming the initial conductive filament includes applying a forming voltage across the bottom and top electrodes 108 and 141 by way of the transistor 103 and the upper conductive structure 120. The forming voltage may knock oxygen atoms out of a lattice in the resistive switching structure 110, thereby forming localized oxygen vacancies that tend to align in the region 115 to form the initial conductive filament. Thereafter, set or reset voltages can be applied across the bottom and top electrodes 108 and 141 to change a resistivity of the resistive switching structure 110 between the HRS and the LRS.

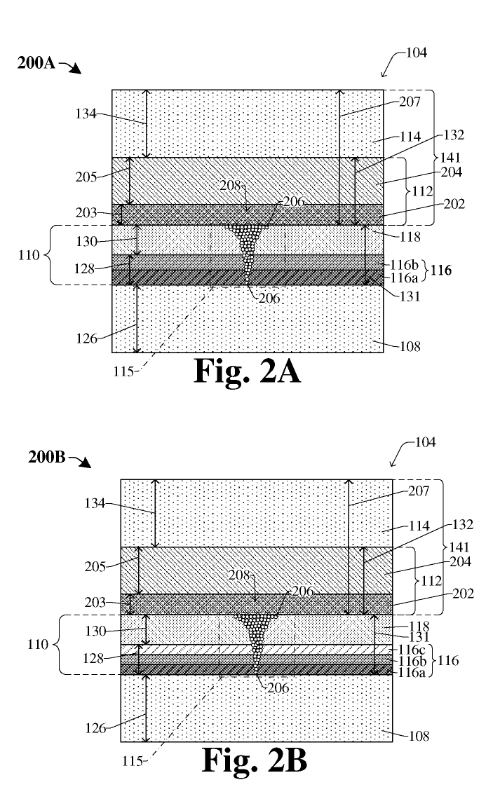

The top electrode 141 of the RRAM cell 104 includes a capping structure 112 to facilitate absorption of oxygen ions. FIG. 2A provides a cross-sectional view 200A providing a more detailed view of the layers in the RRAM cell 104 of FIG. 1 for embodiments in which the capping structure 112 includes a capping metal layer 204 and an optional diffusion barrier layer 202. The diffusion barrier layer 202 is directly between the capping metal layer 204 and the higher oxygen affinity switching layer 118. In addition to the capping structure 112, the top electrode 141 may include an upper metal layer 114 over the capping structure 112. The lower oxygen affinity switching layer 116 is between the higher oxygen affinity switching layer 118 and the bottom electrode 108 and may directly contact the bottom electrode 108.

In some embodiments, the RRAM cell 104 relies on redox reactions during operation to form and dissolve a conductive filament 208 in a region 115 of the resistive switching structure 110. The conductive filament 208 extends from the bottom electrode 108 to the capping structure 112. Forming the conductive filament 208 in the region 115 produces the LRS, and dissolving the conductive filament 208 along at least a portion of a thickness 131 of the resistive switching structure 110 produces the HRS. Thus, the RRAM cell 104 can be switched between the LRS and the HRS by applying appropriate biases to the RRAM cell 104 to form and dissolve the conductive filament 208 in the region 115. In some embodiments, the conductive filament 208 includes oxygen vacancies 206 disposed within the region 115 and extending between the bottom electrode 108 and the capping structure 112.

In some embodiments, the capping structure 112 is configured to absorb oxygen ions from the resistive switching structure 110 during set operations and to release oxygen ions to the resistive switching structure 110 during reset operations. This functioning as an oxygen ion reservoir facilitates the formation and dissolution of the conductive filament 208 in the region 115. In some embodiments, the capping metal layer 204 comprises one or more layers of metals with high oxygen ion solubility such as tantalum (Ta), titanium (Ti), hafnium (Hf), zirconium (Zr), nickel (Ni), iridium (Ir), or the like.

The diffusion barrier layer 202 is a portion of the capping structure 112 provided to restrict or slow the transport of oxygen ions between the capping structure 112 to the resistive switching structure 110, thereby mitigating spontaneous diffusion of oxygen ions that could adversely affect the stability of the RRAM cell 104. In some embodiments, the diffusion barrier layer 202 is or comprises tantalum nitride (TaN), titanium nitride (TiN), or the like. In some embodiments, the diffusion barrier layer 202 is a metal nitride of the capping metal layer 204. For example, the diffusion barrier layer 202 may be or comprise tantalum nitride while the capping metal layer 204 is or comprises tantalum.

In some embodiments, a thickness 203 of the diffusion barrier layer 202 is in the range from about 20 angstroms to about 30 angstroms. In some embodiments, the thickness 203 of the diffusion barrier layer 202 is greater than the thickness 130 of the higher oxygen affinity switching layer 118 and is greater than the thickness 128 of the lower oxygen affinity switching layer 116. In some embodiments, a ratio between the thickness 203 of the diffusion barrier layer 202 and the thickness 130 of the higher oxygen affinity switching layer 118 is within a range of about 2 to about 3. If the diffusion barrier layer 202 is too thin, it may allow excessive spontaneous diffusion of oxygen ions. If the diffusion barrier layer 202 is too thick, it may increase the forming voltage excessively.

A thickness 205 of the capping metal layer 204 is, for example, within a range of about 10 to 50 angstroms or some other suitable value. In some embodiments, a ratio between the thickness 131 of the resistive switching structure 110 and the thickness 205 of the capping structure 112 is within the range from about 0.6 to about 1. If the capping structure 112 is too thin, the capping structure 112 may not adequately absorb oxygen ions during set operation. If the capping structure 112 is too thick, oxygen ions may become dispersed in the capping structure 112 and not return to the resistive switching structure 110 during reset operations.

The upper metal layer 114 is another optional layer in the top electrode 141. The upper metal layer 114 has good conductivity but need not absorb oxygen significantly. The upper metal layer 114 may be, for example, tantalum nitride (TaN), titanium nitride (TiN), ruthenium (Ru), platinum (Pt), a combination thereof, or the like. A thickness 134 of the top electrode 141 is, for example, within a range of about 80 to 195 angstroms or some other suitable value. In some embodiments, an overall thickness 207 of the top electrode 141 is in the range from about 125 angstroms to about 275 angstroms. In some embodiments, a ratio between the thickness 131 of the resistive switching structure 110 and the thickness 132 of the capping structure 112 is in the range from about 0.1 to about 0.3.

In some embodiments, a composition of the bottom electrode 108 is selected so that the bottom electrode 108 does not significantly absorb oxygen ions from or release oxygen ions to the resistive switching structure 110. In some embodiments, the bottom electrode 108 is or comprises tantalum nitride (TaN), titanium nitride (TiN), ruthenium (Ru), platinum (Pt), the like, or a combination thereof. The composition of the bottom electrode 108 may be selected to provide a good work function match to the lower oxygen affinity switching layer 116. A thickness 126 of the bottom electrode 108 may be, for example, within a range of about 75 to 90 angstroms or some other suitable value. In some embodiments, the thickness 134 of the top electrode 141 is greater than the thickness 126 of the bottom electrode 108.

FIG. 2B provides a cross-sectional view 200B that corresponds to the RRAM cell 104 of FIG. 1 for a case in which the lower oxygen affinity switching layer 116 can be divided into three distinct sublayers 116a, 116b, and 116c. While all of the sublayers 116a, 116b, and 116c include the dopant metal, the sublayer 116b has a lower concentration of the dopant metal than the sublayer 116a, and the sublayer 116c has a lower concentration of the dopant metal than the sublayer 116b.

In some embodiments, the sublayer 116𝑎, the sublayer 116𝑏, and the sublayer 116𝑐 each have a dopant concentration in the range from 0.1% to about 10% on an atomic basis. In some embodiments, the sublayer 116𝑐 has from about 40% to about 80% the dopant metal concentration of the sublayer 116𝑎. In some embodiments, the sublayer 116𝑐 has from about 50% to about 80% the dopant metal concentration of the sublayer 116𝑎. In some embodiments, the sublayer 116𝑏 has from about 70% to about 95% the dopant metal concentration of the sublayer 116𝑎. In some embodiments, the sublayer 116𝑐 has from about 80% to about 90% the dopant metal concentration of the sublayer 116𝑎. In some of these embodiments, the dopant metal concentration of the sublayer 116𝑎 is 30% or less than a bulk metal concentration in the sublayer 116𝑎.

The sublayers 116a, 116b, and 116c may all have similar thicknesses. In some embodiments, the thinnest of the sublayers 116a, 116b, and 116c is at least 50% a thickness if the thickest of the sublayers 116a, 116b, and 116c. In some embodiments, the sublayers 116a, 116b, and 116c all have the same thickness. Keeping the thicknesses similar helps assures that variations among the sublayers 116a, 116b, and 116c will have an impact of the formation and shape of the conductive filament 208.

While most of the examples in the present disclosure only illustrate the sublayers 116a and 116b, it will be appreciated that any of these examples may be modified to include the sublayers the sublayers 116a, 116b, and 116c as shown in the cross-sectional view 200B of FIG. 2B. It should also be appreciated that there may be a greater number of sublayers in the lower oxygen affinity switching layer 116. In some embodiments, the dopant metal concentration is continuously diminishing through a thickness of the lower oxygen affinity switching layer 116.

FIG. 3 illustrates a cross-sectional view of an integrated chip 300 in accordance with some embodiments. The integrated chip 300 includes an RRAM cell 104A. The RRAM cell 104A may be like the RRAM cell 104 of FIG. 1 except that the RRAM cell 104 comprises a bottom electrode 108A that is narrower than the resistive switching structure 110. Making the bottom electrode 108A narrower than the resistive switching structure 110 may facilitate the formation of a narrow conductive filament 208 (see FIG. 2).

The RRAM cell 104A is over a lower conductive wire 106 disposed within a first inter-metal dielectric (IMD) layer 302. A lower dielectric layer 304 overlies the first IMD layer 302 and a second IMD layer 306 overlies the lower dielectric layer 304. The lower conductive wire 106 is electrically coupled to the RRAM cell 104. The first and second IMD layers 302 and 306 may be or comprise, for example, silicon dioxide, a low-k dielectric material such as undoped silica glass (USG) or carbon-doped silicon dioxide, some other suitable dielectric material, or any combination of the foregoing. The lower dielectric layer 304 may be or comprise, for example, silicon carbide, silicon oxycarbide, silicon nitride, silicon oxynitride, some other suitable dielectric material, or any combination of the foregoing.

A sidewall spacer structure 308 continuously extends around the RRAM cell 104A. The sidewall spacer structure 308 may demarcate edges of the sublayers 116a and 116b. An upper conductive structure 120 overlies and couples to the top electrode 141. The lower conductive wire 106 and the upper conductive structure 120 may be or comprise, for example, aluminum, copper, tungsten, ruthenium, titanium nitride, some other suitable conductive material, or any combination of the foregoing.

In some embodiments, sidewalls of the lower oxygen affinity switching layer 116, the higher oxygen affinity switching layer 118, the diffusion barrier layer 202, the capping metal layer 204, and the top electrode 141 are aligned. The alignment is of a type that results from etching the RRAM cell 104A from a stack comprising all of these layers. The sidewall spacer structure 308 extends along these aligned sidewalls. In some embodiments, sidewall spacer structure 308 extends onto a top surface of the RRAM cell 104A.

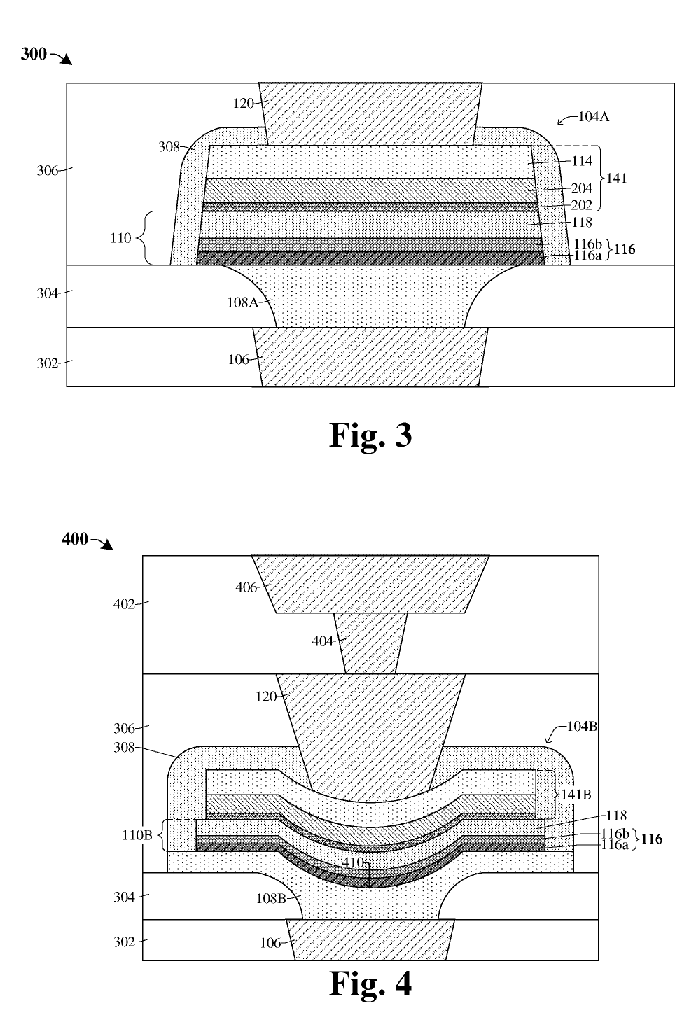

FIG. 4 illustrates a cross-sectional view of an integrated chip 400. The integrated chip 400 includes an RRAM cell 104B in accordance with some embodiments. The RRAM cell 104B includes a bottom electrode 108B, a resistive switching structure 110B, and a top electrode 141B. The bottom electrode 108B, the resistive switching structure 110B, and the top electrode 141B are like the corresponding parts of the RRAM cell 104 of FIG. 1 except for their shapes. The bottom electrode 108B is indented so that it has a curved upper surface 410. The bottom electrode 108B may comprise a peripheral region that extends over a top surface of the lower dielectric layer 304 and a middle region that extends through the lower dielectric layer 304. In the middle region the bottom electrode 108 has the curved upper surface 410.

The layers of the resistive switching structure 110B are disposed on the curved upper surface 410 so that they have corresponding curvatures. The layers of the top electrode 141B are disposed on the resistive switching structure 110B and so have the same curvature, although the curvature may become more relaxed through the height of the top electrode 141B. In particular, the lower oxygen affinity switching layer 116, including, the sublayers 116a and 116b, and the higher oxygen affinity switching layer 118, may have curvatures that mirror the curved upper surface 410. The curvature of the resistive switching structure 110B may promote uniformity of the conductive filaments 208 (see FIG. 2) among a plurality of RRAM cells 104B and thereby improve the reliability of the memory.

In some embodiments, the resistive switching structure 110B is narrower than the bottom electrode 108B. In some embodiments, the top electrode 141B is narrower than the resistive switching structure 110B. In the RRAM cell 104B, this feature may further promote uniformity of the conductive filaments 208 (see FIG. 2) among a plurality of RRAM cells 104B and thereby improve the reliability of the memory.

A third IMD layer 402 may overly the second IMD layer 306. An upper conductive via 404 and an upper conductive wire 406 may be disposed within the third IMD layer 402. The upper conductive via and wire 404 and 406 are electrically coupled to the RRAM cell 104 by way of the upper conductive structure 120. The upper conductive structure 120 may be a top electrode via.

FIG. 5 illustrates a cross-sectional view of an integrated chip 500. The integrated chip 500 includes an RRAM cell 104C having a resistive switching structure 110C in accordance with some embodiments. The integrated chip 500, the RRAM cell 104C, and the resistive switching structure 110C, are like the integrated chip 400, the RRAM cell 104B, and the resistive switching structure 110B of FIG. 4 except that the resistive switching structure 110C includes an additional layer: a still higher oxygen affinity layer 502 over the higher oxygen affinity switching layer 118. The still higher oxygen affinity layer 502 comprises the oxide of a metal having a higher oxygen affinity than the metal of the higher oxygen affinity switching layer 118. In some embodiments, the still higher oxygen affinity layer 502 comprises an oxide of a metal having a standard Gibbs free energy of oxide formation of about -1100 kJ/mol O₂ or less. In some embodiments, the still higher oxygen affinity layer 502 comprises an oxide of a metal having a standard Gibbs free energy of oxide formation at least about -100 kJ/mol O₂ less than the standard Gibbs free energy of oxide formation of the metal of the higher oxygen affinity switching layer 118. The still higher oxygen affinity layer 502 may facilitate the formation of intrinsic oxygen vacancies and further lower the forming voltage.

In some embodiments, a thickness of the still higher oxygen affinity layer 502 is equal to or less than a thickness of the lower oxygen affinity switching layer 116. In some embodiments, the thickness of the still higher oxygen affinity layer 502 is equal to or less than the thickness of the higher oxygen affinity switching layer 118. The thickness of the still higher oxygen affinity layer 502 may be, for example, within a range of about 10 to 15 angstroms or some other suitable value. If the still higher oxygen affinity layer 502 is too thick, it may increase the forming voltage. If the still higher oxygen affinity layer 502 is too thin, it may not be effective for lowering the forming voltage.

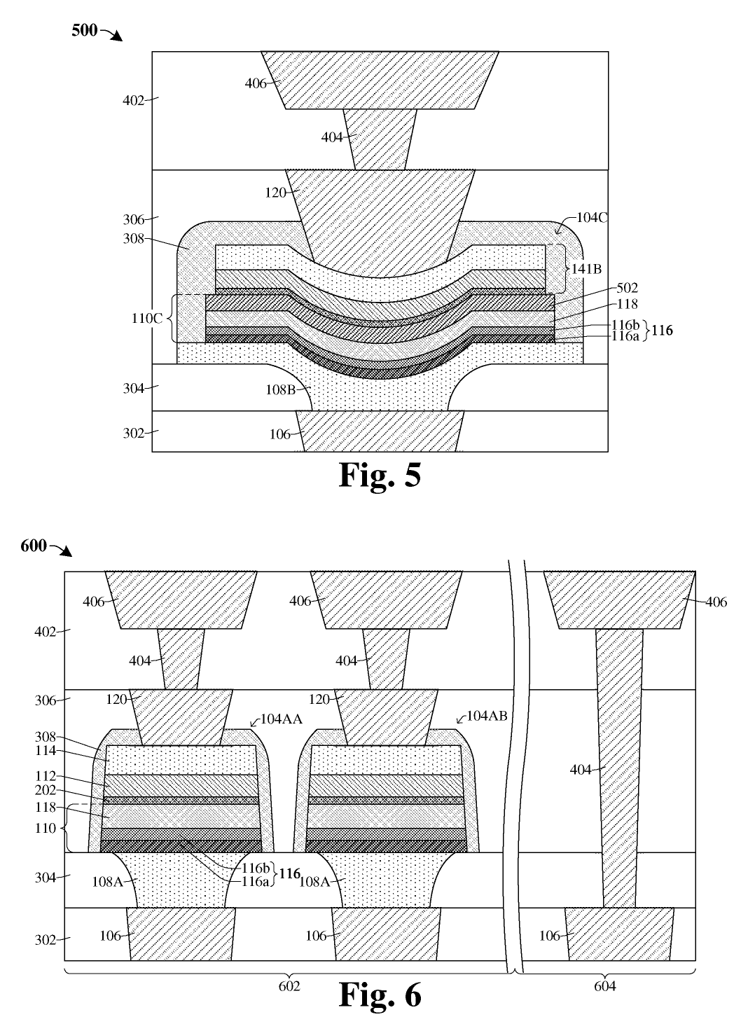

FIG. 6 illustrates a cross-sectional view of an integrated chip 600 comprising a memory region 602 laterally adjacent to a logic region 604. The integrated chip 600 comprises a first RRAM cell 104AA and a second RRAM cell 104AB, which are elements in an array disposed within the memory region 602. The first and second RRAM cells 104AA and 104AB may be configured as the RRAM cell 104B of FIG. 3 or like any of the other RRAM cells of the present disclosure. An upper conductive via 404 may be disposed within the logic region 604 and extend continuously from an upper conductive wire 406 to a lower conductive wire 106 in the logic region 604.

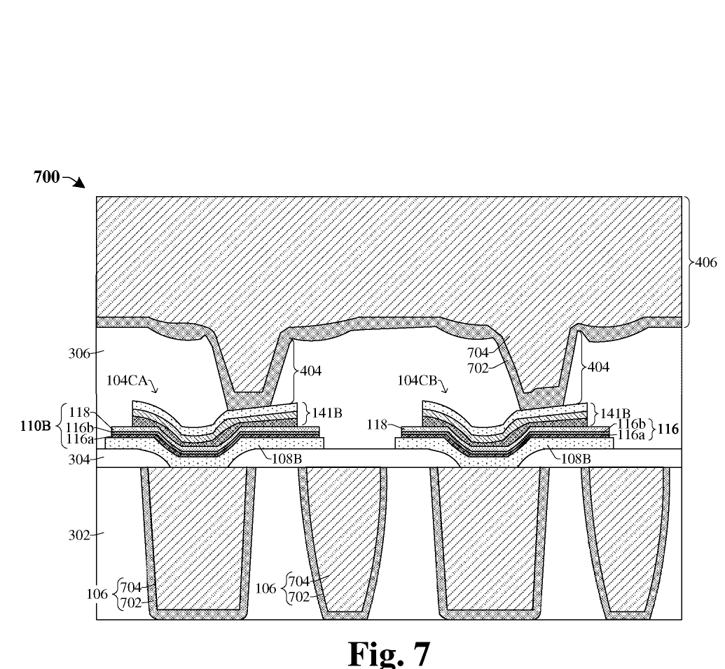

FIG. 7 illustrates a cross-sectional view of an integrated chip 700 comprising a first RRAM cell 104CA and a second RRAM cell 104CB laterally adjacent to one another. The first and second RRAM cells 104CA and 104CB may have the structural features of the RRAM cell 104B of FIG. 4, of the RRAM cell 104C of FIG. 5, or some other RRAM cell of the present disclosure.

The integrated chip 700 comprises a plurality of lower conductive wires 106 underlying the first and second RRAM cells 104CA and 104CB. A plurality of upper conductive vias 404 and an upper conductive wire 406 overlying the first and second RRAM cells 104CA and 104CB. The plurality of lower conductive wires 106, the plurality of upper conductive vias 404, and the upper conductive wire 406 each comprise a conductive body 704 and a conductive liner 702. In some embodiments, the conductive liner 702 extends along a lower surface and opposing sidewalls of the conductive body 704. The conductive body 704 may be or comprise, for example, copper (Cu), aluminum (Al), tungsten (W), ruthenium (Ru), a combination of the foregoing, or the like. The conductive liner 702 may be or comprise, for example, titanium nitride (TiN), tantalum nitride (TaN), or the like. In some embodiments, the upper conductive wire 406 laterally extends continuously from over the first RRAM cell 104CA to over the second RRAM cell 104CB. Layers in the first and second RRAM cells 104CA and 104CB respectively have a protrusion segment extending downward towards a corresponding lower conductive wire 106. In some embodiments, the upper conductive vias 404 are laterally offset from the protrusion segments of the first and second RRAM cells 104CA and 104CB.

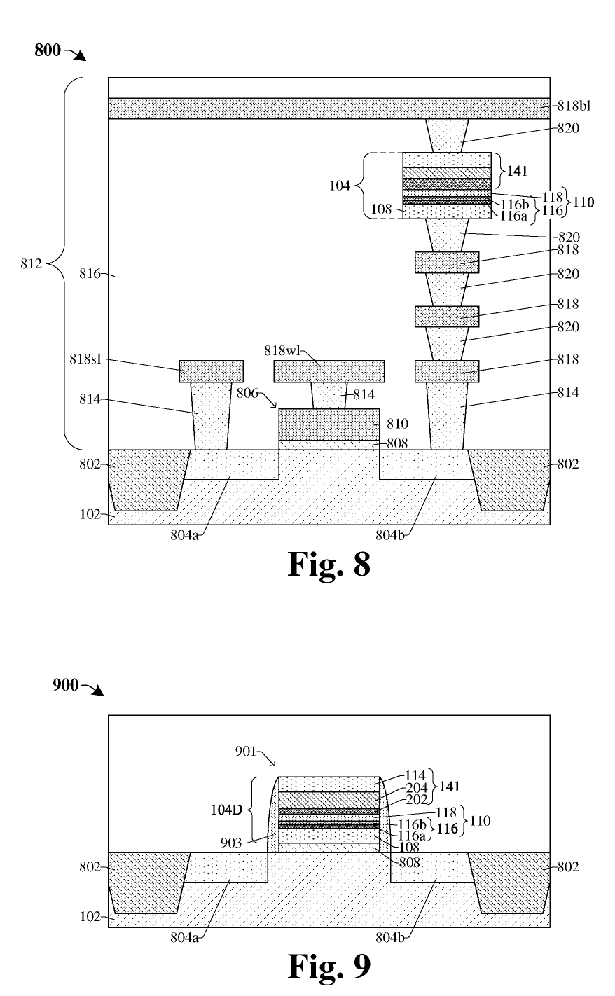

FIG. 8 illustrates a cross-sectional view of an integrated chip 800 having the RRAM cell 104 disposed within an interconnect structure 812 that overlies a substrate 102. Another RRAM cell 104 of the present disclosure could be used in place of the RRAM cell 104 in the integrated chip 800. The integrated chip 800 includes a semiconductor device 806 disposed on the substrate 102. The semiconductor device 806 may be, for example, a metal-oxide semiconductor field-effect transistor (MOSFET), a bipolar junction transistor (BTJ), a high-electric-mobility transistor (HEMT), any other front-end-of-line semiconductor device, or the like. The semiconductor device 806 comprises a gate dielectric layer 808, a gate electrode 810 over the gate dielectric layer 808, and a pair of source/drain regions 804𝑎-804𝑏. An isolation structure 802 is disposed within the substrate 102 and is configured to electrically isolate the semiconductor device 806 from other devices (not shown) disposed within and/or on the substrate 102. Source/drain region(s) may refer to a source or a drain, individually or collectively dependent upon the context. The semiconductor device 806 may be an access control device for the RRAM cell 104.

An interconnect structure 812 is disposed over the substrate 102 and the semiconductor device 806. The interconnect structure 812 may comprise an interconnect dielectric structure 816, a plurality of conductive contacts 814, a plurality of conductive traces 818 (e.g., metal traces), and a plurality of conductive vias 820 (e.g., metal vias). The plurality of conductive traces are arranged in metallization layers separated by via layers. The plurality of conductive contacts 814, the plurality of conductive traces 818, and the plurality of conductive vias 820 are electrically coupled in a predefined manner and configured to provide electrical connections between various devices disposed throughout the integrated chip 800. The plurality of conductive contacts 814, the plurality of conductive traces 818, and/or the plurality of conductive vias 820 may be or comprise, for example, titanium nitride (TiN), tantalum nitride, tungsten (W), ruthenium (Ru), aluminum (Al), copper (Cu), the like, another conductive material, or some combination of the foregoing. The interconnect dielectric structure 816 may comprises one or more inter-metal dielectric layers, which may respectively comprise a low-k dielectric material, an oxide (e.g., silicon dioxide), another dielectric material, or any combination of the foregoing

A first one of the plurality of conductive traces 818 is denoted as 818𝑤𝑙 and may be referred to as a word line. In some embodiments, the word line 818𝑤𝑙 may be electrically coupled to the gate electrode 810 of the semiconductor device 806 via the interconnect structure 812. A second one of the plurality of conductive traces 818 is denoted as 818𝑠𝑙 and may be referred to as a source line. In further embodiments, the source line 818𝑠𝑙 may be electrically coupled to a first source/drain region 804𝑎 of the semiconductor device 806 via the interconnect structure 812. A third one of the plurality of conductive traces 818 is denoted as 818𝑏𝑙 and may be referred to as a bit line. In yet further embodiments, the bit line 818𝑏𝑙 may be electrically coupled to the top electrode 141 of the RRAM cell 104 and the bottom electrode 108 may be electrically coupled to a second source/drain region 804𝑏 of the semiconductor device 806 via the interconnect structure 812.

In some embodiments, the RRAM cell 104 is electrically coupled to a second source/drain region 804b of the semiconductor device 806 via the interconnect structure 812. Thus, in some embodiments, application of a suitable word line voltage to the word line 818wl may electrically couple the RRAM cell 104 between the bit line 818bl and the source line 818sl. Consequently, by providing suitable bias conditions, the RRAM cell 104 can be read or switched between one two distinct data states. A current through the RRAM cell 104 also passes through the semiconductor device 806. Accordingly, in order to allow the semiconductor device 806 to be scaled down, the RRAM cell 104 is designed to operate at lower voltages.

FIG. 9 illustrates a cross-sectional view of an integrated chip 900 having a flash memory cell 901 disposed over the substrate 102. The flash memory cell 901 has the structure of a transistor with an RRAM cell 104D in place of the gate electrode. The flash memory cell 901 includes the source/drain regions 804𝑎-804𝑏, the gate dielectric layer 808, and the RRAM cell 104D. A spacer 903 may surround the portion of the flash memory cell 901 that includes the gate dielectric layer 808 and the RRAM cell 104D.

The RRAM cell 104D include a bottom electrode 108, a resistive switching structure 110, and a top electrode 141. The bottom electrode 108, the resistive switching structure 110, and the top electrode 141 may have compositions, thicknesses, and other characteristics in accordance with any of the examples of the present disclosure. As with the other examples of the present disclosure, the order of layers in RRAM cell 104D may be reversed within the flash memory cell 901, although in reversing the order of layers the higher oxygen affinity switching layer 118 should remain closer than the lower oxygen affinity switching layer 116 to the electrode that contains the capping metal layer 204, which has solubility for oxygen ions. Likewise, the sublayer 116𝑏 with the lower dopant metal concentration should remain closer to the higher oxygen affinity switching layer 118 than the sublayer 116𝑎.

In the flash memory cell 901, the bottom electrode 108 is a floating gate electrode. Nevertheless, the RRAM cell 104D may be set to the LRS and reset to the HRS by applying suitable voltages between the source/drain regions 804𝑎-804𝑏 and the top electrode 141. The top electrode 141 serves as a gate electrode for the flash memory cell 901. Switching the RRAM cell 104D between the LRS and the HRS varies a capacitance of the RRAM cell 104D and thus varies a threshold voltage of the flash memory cell 901. The state of the flash memory cell 901 may be determined by applying a voltage to the top electrode 141 that is between the higher threshold voltage, which corresponds to the LRS, and the lower threshold voltage, which corresponds to the HRS. In some embodiments, the flash memory cell 901 has threshold voltages less than or equal to about 2.0V in both the HRS and the LRS.

Providing the RRAM cell 104D with a resistive switching structure 110 according to the present disclosure greatly increases the endurance of the flash memory cell 901 because the resistive switching structure 110 that provides a low forming voltage allows the RRAM cell 104D to be set, reset, and read without progressively damaging the gate dielectric layer 808. The gate dielectric layer 808 may be silicon dioxide (SiO2). In some embodiments, however, the gate dielectric layer 808 is a high ĸ dielectric. The high ĸ dielectric may be a metal oxide or a silicate of hafnium (Hf), aluminum (Al), zirconium (Zr), lanthanum (La), magnesium (Mg), barium (Ba), titanium (Ti), lead (Pb), or the like. Examples include hafnium-based materials such as hafnium oxide (HfO2), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO2-Al2O3) alloy, and the like. Additional examples include, without limitation, zirconium oxide (ZrO2), tantalum oxide (Ta2O5), aluminum oxide (Al2O3), yttrium oxide (Y2O3), lanthanum oxide (La2O3), strontium titanium oxide (SrTiO3), and the like. The gate dielectric layer 808 may have a thickness in the range from about 4 Å to about 100 Å. In some embodiments, the gate dielectric layer 808 has a thickness in the range from about 5 Å to about 25 Å.

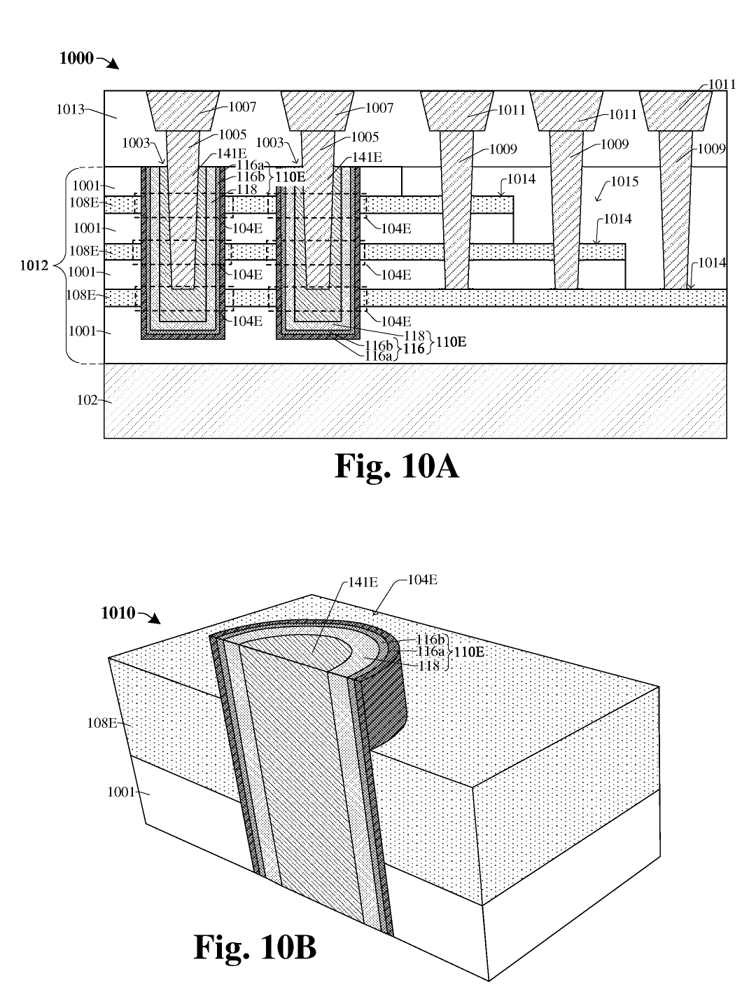

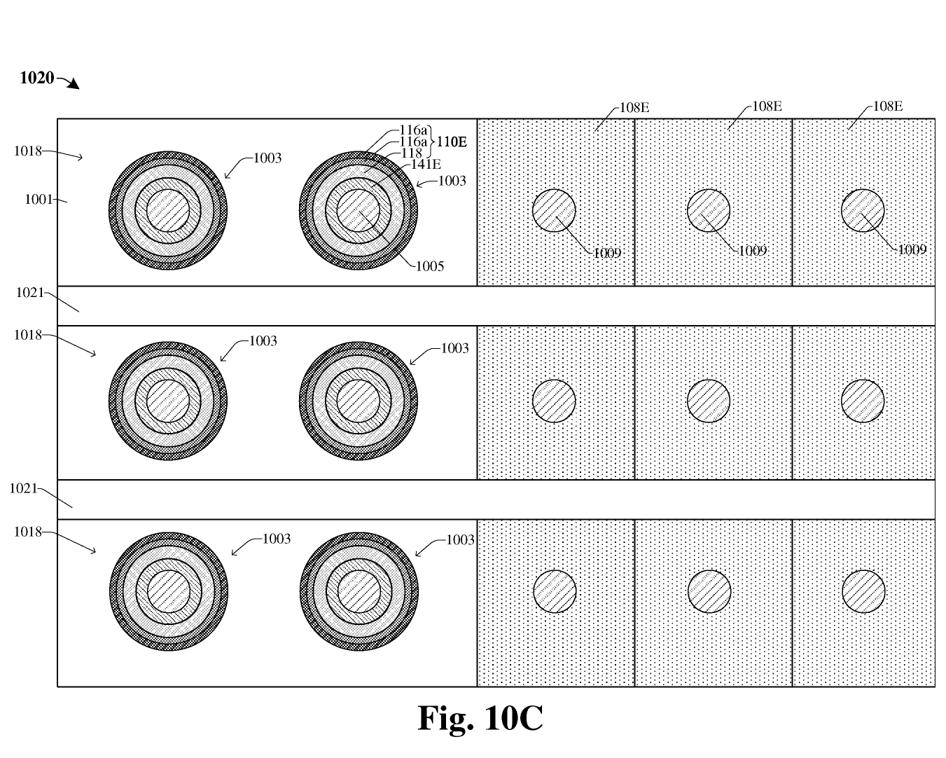

FIG. 10A illustrates a cross-sectional view of an integrated chip 1000 having a three-dimensional (3D) array of RRAM cells 104E disposed over a substrate 102. FIG. 10B illustrates a cutaway perspective view 1010 illustrating one of the RRAM cells 104E in the 3D array. The bottom electrodes 108E are provided by horizontal layers in a stack 1012. Within the stack 1012 the bottom electrodes 108E are interleaved with dielectric layers 1001. The stack 1012 is illustrated with three layers containing bottom electrodes 108E but may have a smaller or larger number of bottom electrode layers. Vias 1003 through the stack 1012 contain top electrodes 141E. The top electrodes 141E are lined with the resistive switching structure 110E so that the resistive switching structure 110E has a cylindrical form. The RRAM cells 104E are formed at intersections between the top electrodes 141E and the bottom electrodes 108E at locations where a top electrode 141E and a bottom electrode 108E are separated only by a thickness of the resistive switching structure 110E.

The bottom electrodes 108E jut out on one side of the stack 1012 to form ledges 1014 in a staircase pattern 1015. Vias 1009 land on the ledges 1014 to couple wires 1011 to the bottom electrodes 108E. Vias 1005 couple wires 1007 to the top electrodes 141E. By selecting one of the wires 1007 and one of the wires 1011, any of the RRAM cells 104E in the 3D array may be individually addressed.

FIG. 10C illustrates a plan view 1020 of the integrated chip 1000. Dielectric-filled trenches 1021 shown in FIG. 10C may cut through the bottom electrodes 108E (see FIG. 10A) to divide the 3D array into sectors 1018. One row of vias 1003 is illustrated in each sector 1018, but each sector 1018 may include a plurality of rows of vias 1003. The vias 1003 in adjacent rows may be aligned or staggered.

The integrated chip 1000 has been describes as having the bottom electrodes in horizontal layers and the top electrode as being in vias 1003 through the stack 1012, however the electrode designed to have oxygen solubility may be in the horizontal layers and the electrode with little or no oxygen solubility may be in the vias 1003. In either case, the higher oxygen affinity switching layer 118 of the resistive switching structure 110E should be closer to the electrode that is configured to have oxygen solubility. If the electrode having higher oxygen solubility includes multiple layers, the manufacturing process may be simpler if the electrode having higher oxygen solubility is in the vias 1003.

In a 3D RRAM array, loading resistances tends to consume the voltages that are applied to program, read, and erase the RRAM cells. This can be problematic in a 3D RRAM array having conventional RRAM cells. A 3D RRAM array with resistive switching structures according to the present disclosure solves the problem of loading resistances by allowing the memory to operate at lower voltages, e.g., 2V or less.

FIGS. 11-16 illustrate a series of cross-sectional views 1100-1600 of an integrated chip comprising a resistive switching structure according to the present disclosure at various stages of manufacture according to a process of the present disclosure. Although FIGS. 11-16 are described in relation to a series of acts, it will be appreciated that the order of the acts may in some cases be altered and that this series of acts are applicable to structures other than the ones illustrated. In some embodiments, some of these acts may be omitted in whole or in part. Furthermore, it will be appreciated that the structures shown in FIGS. 11-16 are not limited to a method of manufacture but rather may stand alone as structures separate from the method.

As shown in cross-sectional view 1100 of FIG. 11, a first inter-metal dielectric (IMD) layer 302 may be formed over a substrate 102 and a lower conductive wire 106 may be formed within the first IMD layer 302. The substrate 102 may be or comprise, for example, silicon, monocrystalline silicon, silicon-germanium, a silicon-on-insulator (SOI) substrate, one or more epitaxial layers, some other suitable substrate or any combination of the foregoing. The first IMD layer 302 may be formed over the substrate 102 by, for example, chemical vapor deposition (CVD), physical vapor deposition (PVD), atomic layer deposition (ALD), or some other suitable growth or deposition process. In some embodiments, the lower conductive wire 106 is formed by etching the first IMD layer 302 to form an opening in the first IMD layer 302 and depositing (e.g., by PVD, CVD, electroplating, electroless plating, etc.) the lower conductive wire 106 in the opening.

A lower dielectric layer 304 is formed over the lower conductive wire 106 and a bottom electrode 108 is formed within the lower dielectric layer 304. The lower dielectric layer 304 may be formed over the lower conductive wire 106 by, for example, CVD, PVD, ALD, or some other suitable growth or deposition process. In some embodiments, a process for forming the bottom electrode 108 includes: forming a masking layer (not shown) over the lower dielectric layer 304; etching (e.g., wet etching, dry etching, etc.) the lower dielectric layer 304 to form an opening over the lower conductive wire 106; depositing (e.g., by PVD, CVD, electroplating, electroless plating, etc.) a bottom electrode material within the opening; and performing a planarization process (e.g., chemical mechanical polishing (CMP)) to remove excess bottom electrode material.

The first IMD layer 302 may be or comprise, for example, silicon dioxide, a low-k dielectric material such as undoped silica glass (USG) or carbon-doped silicon dioxide, some other suitable dielectric material, or any combination of the foregoing. The lower conductive wire 106 may be or comprise, for example, aluminum (Al), copper (Cu), tungsten (W), ruthenium (Ru), titanium nitride (TiN), the like, or any combination of the foregoing. The lower dielectric layer 304 may be or comprise, for example, silicon oxide (SiO), silicon carbide (SiC), silicon oxycarbide (SiOC), silicon nitride (SiN), silicon oxynitride (SiON), the like, some other dielectric material, or any combination of the foregoing.

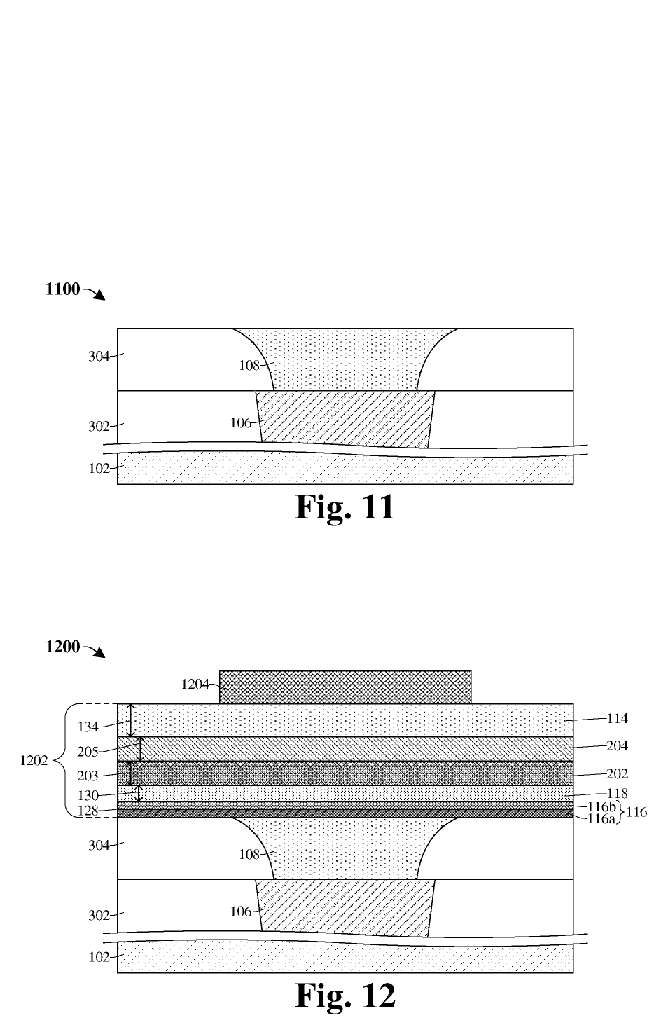

As shown in cross-sectional view 1200 of FIG. 12, a stack of memory layers 1202 may be formed over the bottom electrode 108 and a masking layer 1204 may be formed over the stack of memory layers 1202. In some embodiments, the stack of memory layers 1202 includes: the lower oxygen affinity switching layer 116, the higher oxygen affinity switching layer 118, the diffusion barrier layer 202, the capping metal layer 204, and an upper metal layer 114. The layers within the stack of memory layers 1202 may be formed by CVD, PVD, ALD, electroplating, electroless plating, the like, or any other suitable growth or deposition process(es). The masking layer 1204 is formed with a pattern such that the masking layer 1204 covers a region of the stack of memory layers 1202 (e.g., over the bottom electrode 108) and leaves surrounding areas of the stack of memory layers 1202 exposed.

In some embodiments, the lower oxygen affinity switching layer 116 and the higher oxygen affinity switching layer 118 are formed by ALD. In some embodiments, the lower oxygen affinity switching layer 116 includes a bulk metal oxide and a dopant metal oxide and the dopant metal oxide is deposited in distinct ALD cycles from the bulk metal oxide. In some embodiments, a ratio between bulk metal oxide deposition cycles and dopant metal oxide deposition cycles is greater when depositing the sublayer 116b than when deposition the sublayer 116a.

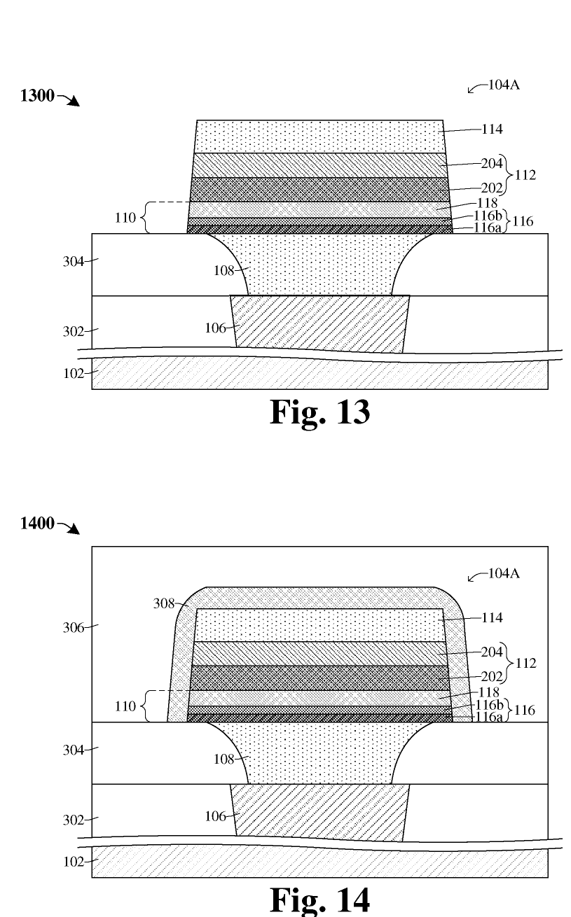

As shown in cross-sectional view 1300 of FIG. 13, an etch process may be performed to pattern the stack of memory layers 1202 (see FIG. 12) according to the masking layer 1204, thereby shaping the resistive switching structure 110, the capping structure 112, and the RRAM cell 104A. The etching process may comprise, for example, one or more dry etching processes, wet etching processes, a combination thereof, or the like. The masking layer 1204 (see FIG. 12) may be removed during or after the patterning process.

As shown in cross-sectional view 1400 of FIG. 14, a sidewall spacer structure 308 is formed over and around the RRAM cell 104A, and a second IMD layer 306 is formed over the sidewall spacer structure 308 and the lower dielectric layer 304. The sidewall spacer structure 308 may be formed over the RRAM cell 104A by, for example, CVD, PVD, ALD, or some other suitable growth or deposition process. The second IMD layer 306 may be formed over the lower dielectric layer 304 by, for example, CVD, PVD, ALD, or some other suitable growth or deposition process.

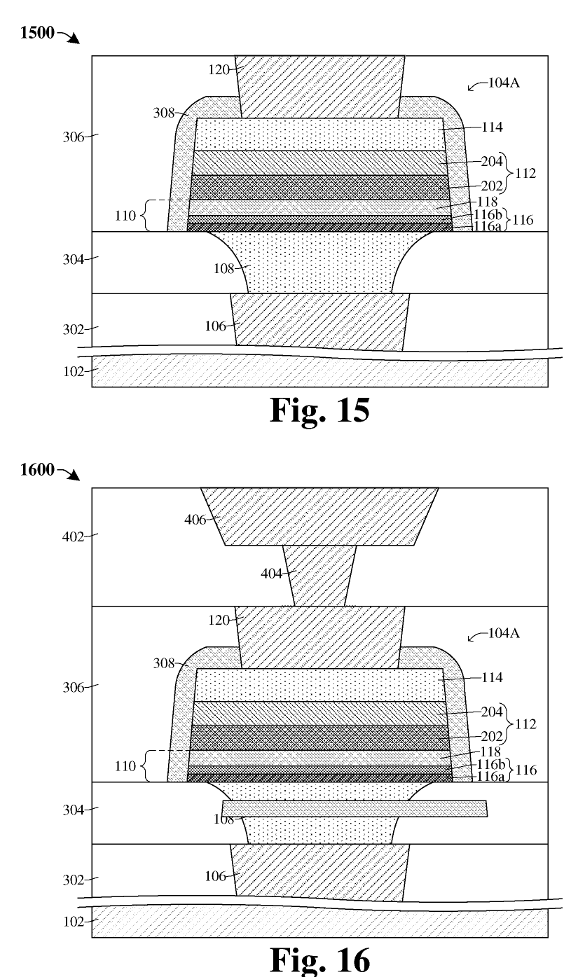

As shown in cross-sectional view 1500 of FIG. 15, an upper conductive structure 120 is formed over the top electrode 141. In some embodiments, a process of forming the upper conductive structure 120 includes: depositing a masking layer (not shown) over the second IMD layer 306; patterning the second IMD layer 306 and the sidewall spacer structure 308 according to the masking layer, thereby forming an opening over the top electrode 141; depositing (e.g., by CVD, PVD, electroplating, electroless plating, etc.) a conductive material (e.g., comprising aluminum, copper, titanium, tantalum, titanium nitride, tantalum nitride, etc.) in the opening; and performing a planarization process (e.g., a CMP process) on the conductive material.

As shown in cross-sectional view 1600 of FIG. 16, a third IMD layer 402 is formed over the second IMD layer 306, and an upper conductive via 404 and an upper conductive wire 406 are formed within the third IMD layer 402. The third IMD layer 402 is formed over the second IMD layer 306 by, for example, CVD, PVD, ALD, or some other suitable deposition or growth process. In some embodiments, forming the upper conductive via 404 and the upper conductive wire 406 includes: etching the third IMD layer 402 to form one or more openings in the third IMD layer 402; depositing (e.g., by CVD, PVD, ALD, sputtering, electro plating, etc.) a conductive material (e.g., aluminum, copper, titanium nitride, tantalum nitride, ruthenium, etc.) in the one or more openings, and performing a planarization process (e.g., a CMP process) on the conductive material. The third IMD layer 402 may be or comprise, for example, silicon dioxide, a low-k dielectric material such as USG or carbon-doped silicon dioxide, some other suitable dielectric material, or any combination of the foregoing.

FIGS. 17-23 illustrate a series of cross-sectional views 1700-2300 of an integrated chip comprising a resistive switching structure according to the present disclosure at various stages of manufacture according to another process of the present disclosure. Although FIGS. 17-23 are described in relation to a series of acts, it will be appreciated that the order of the acts may in some cases be altered and that this series of acts are applicable to structures other than the ones illustrated. In some embodiments, some of these acts may be omitted in whole or in part. Furthermore, it will be appreciated that the structures shown in FIGS. 17-23 are not limited to a method of manufacture but rather may stand alone as structures separate from the method.

As shown in cross-sectional view 1700 of FIG. 17, a first inter-metal dielectric (IMD) layer 302 is formed over a substrate 102 and a lower conductive wire 106 is formed within the first IMD layer 302. The first IMD layer 302 and the lower conductive wire 106 may be formed as illustrated and/or described in FIG. 11. Further, a lower dielectric layer 304 may be formed over the lower conductive wire 106. The lower dielectric layer 304 may be formed by, for example, CVD, PVD, ALD, or some other suitable process.

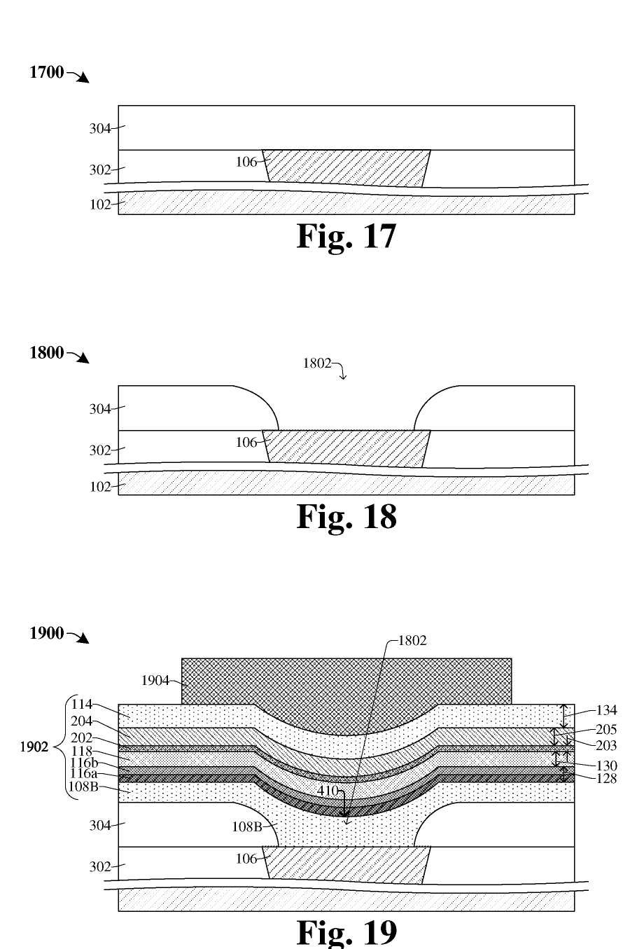

As shown in cross-sectional view 1800 of FIG. 18, a patterning process is performed on the lower dielectric layer 304 to form an opening 1802 in the lower dielectric layer 304. In some embodiments, the patterning process includes forming a masking layer (not shown) over the lower dielectric layer 304 and exposing unmasked regions of the lower dielectric layer 304 to one or more etchants. The patterning process may comprise, for example, a wet etch process, a dry etch process, or the like.

As shown in cross-sectional view 1900 of FIG. 19, a stack of memory layers 1902 is formed over the lower conductive wire 106 and the lower dielectric layer 304, thereby filling the opening (1802 of FIG. 18). In some embodiments, the stack of memory layers 1902 includes: the bottom electrode 108B, the lower oxygen affinity switching layer 116, the higher oxygen affinity switching layer 118, the diffusion barrier layer 202, the capping metal layer 204, and the top electrode 141. The memory layers 1902 may be formed by CVD, PVD, ALD, electroplating, electroless plating, or another suitable growth or deposition process(es). The bottom electrode 108 is formed so that it has a curved upper surface 410 with an indentation corresponding to the opening 1802. In some embodiments, the lower oxygen affinity switching layer 116 and the higher oxygen affinity switching layer 118 are formed by ALD so that they conform in shape to the curved upper surface 410. A masking layer 1904 may be formed over the stack of memory layers 1902, wherein the masking layer 1904 defines the shape of a memory cell centered over the opening 1802.

In some embodiments, the lower oxygen affinity switching layer 116 and the higher oxygen affinity switching layer 118 are formed by ALD so that they conform in shape to the curved upper surface 410. In some embodiments, the lower oxygen affinity switching layer 116 includes a bulk metal oxide and a dopant metal oxide and the dopant metal oxide is deposited in distinct ALD cycles from the bulk metal oxide. In some embodiments, a ratio between bulk metal oxide deposition cycles and dopant metal oxide deposition cycles is greater when depositing the sublayer 116b than when deposition the sublayer 116a. A masking layer 1904 may be formed over the stack of memory layers 1902, wherein the masking layer 1904 defines the shape of a memory cell centered over the opening 1802.

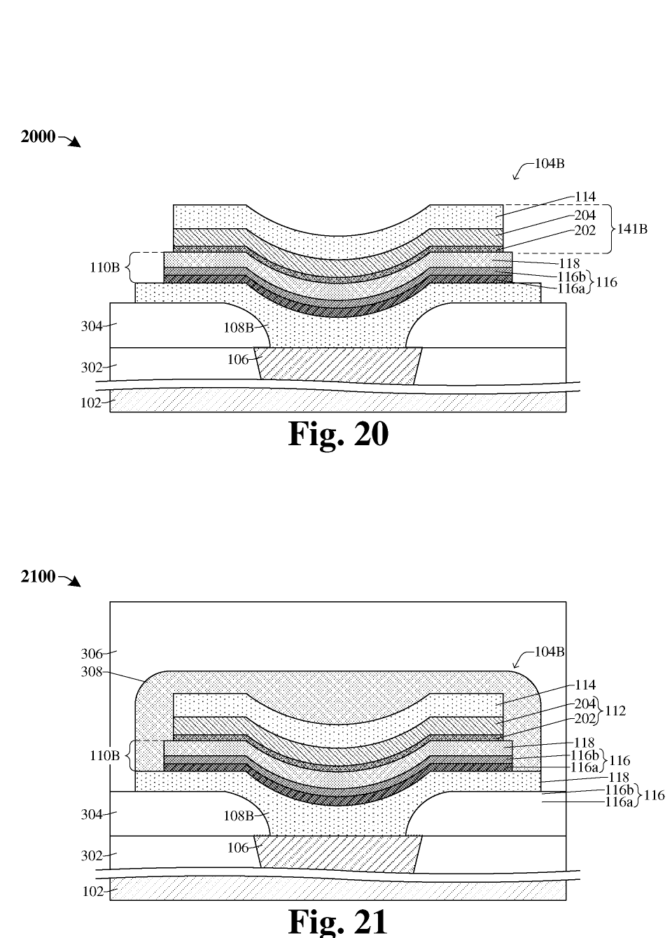

As shown in cross-sectional view 2000 of FIG. 20, a patterning process is performed on the stack of memory layers 1902 (see FIG. 19), thereby defining the resistive switching structure 110B, the top electrode 141B, and the RRAM cell 104B. In some embodiments, the patterning process includes exposing unmasking regions (e.g., in the peripheral region) of the layers in the stack of memory layers 1902 to one or more etchants. The patterning process may comprise, for example, one or more dry etching process, one or more wet etching process, or the like. The masking layer 1904 (see FIG. 19) may be removed during or after the patterning process.

As shown in cross-sectional view 2100 of FIG. 21, a sidewall spacer structure 308 may be formed over and around the RRAM cell 104, and a second IMD layer 306 may be formed over the sidewall spacer structure 308 and the lower dielectric layer 304. The sidewall spacer structure 308 may be formed by, for example, CVD, PVD, ALD, or some other suitable growth or deposition process. The second IMD layer 306 may be formed over the lower dielectric layer 304 by, for example, CVD, PVD, ALD, or some other suitable growth or deposition process.

As shown in cross-sectional view 2200 of FIG. 22, an upper conductive structure 120 may be formed over the top electrode 141. In some embodiments, a process for forming the upper conductive structure 120 includes: depositing a masking layer (not shown) over the second IMD layer 306; patterning the second IMD layer 306 and the sidewall spacer structure 308 according to the masking layer, thereby forming an opening over the top electrode 141; depositing (e.g., by CVD, PVD, electroplating, electroless plating, etc.) a conductive material (e.g., comprising aluminum, copper, titanium, tantalum, titanium nitride, tantalum nitride, etc.) in the opening; and performing a planarization process (e.g., a CMP process) on the conductive material.

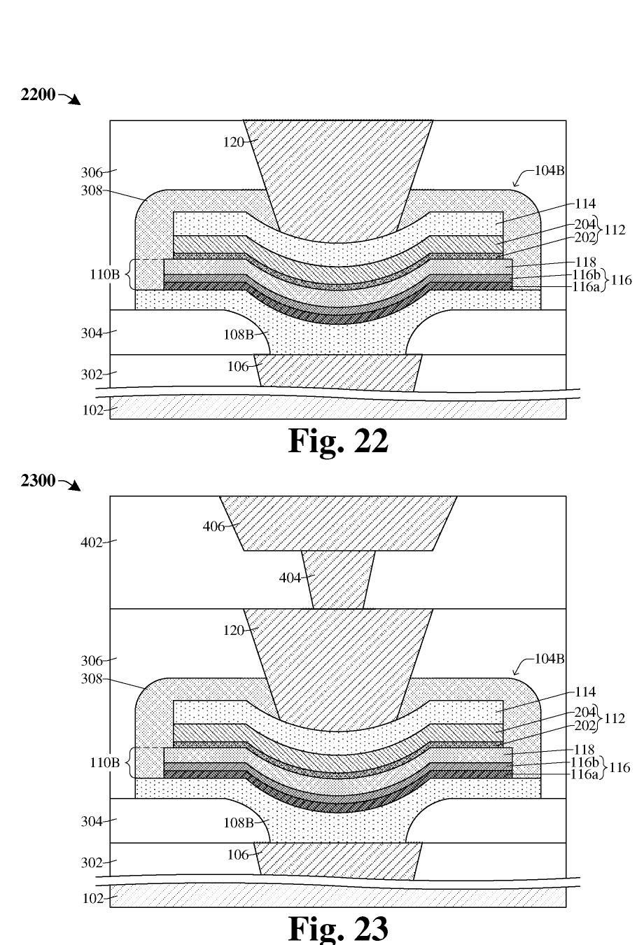

As shown in cross-sectional view 2300 of FIG. 23, the third IMD layer 402 is formed over the second IMD layer 306, and the upper conductive via 404 and the upper conductive wire 406 are formed within the third IMD layer 402. The third IMD layer 402 is formed over the second IMD layer 306 by, for example, CVD, PVD, ALD, or some other suitable deposition or growth process. In some embodiments, forming the upper conductive via 404 and the upper conductive wire 406 includes: etching the third IMD layer 402 to form one or more openings in the third IMD layer 402; depositing (e.g., by CVD, PVD, ALD, sputtering, electro plating, etc.) a conductive material (e.g., aluminum, copper, titanium nitride, tantalum nitride, ruthenium, etc.) in the one or more openings, and performing a planarization process (e.g., a CMP process) on the conductive material.

FIGS. 24-27 illustrate a series of cross-sectional views 2400-2700 of an integrated chip according to the present disclosure at various stages of a manufacturing by a process according to some embodiments. Although FIGS. 24-27 are described in relation to a series of acts, it will be appreciated that the order of the acts may in some cases be altered and that this series of acts are applicable to structures other than the ones illustrated. In some embodiments, some of these acts may be omitted in whole or in part. Furthermore, it will be appreciated that the structures shown in FIGS. 24-27 are not limited to a method of manufacture but rather may stand alone as structures separate from the method. The process is illustrated as forming the integrated chip 900 of FIG. 9, which comprises the flash memory cell 901, but may be applied to manufacturing other integrated chips according to the present disclosure.

As shown in cross-sectional view 2400 of FIG. 24, the process may begin with forming the isolation structures 802 in the substrate 102. In this example, the substrate 102 is a semiconductor substrate. The process may include etching trenches in the substrate 102 and filling the trenches with dielectric.

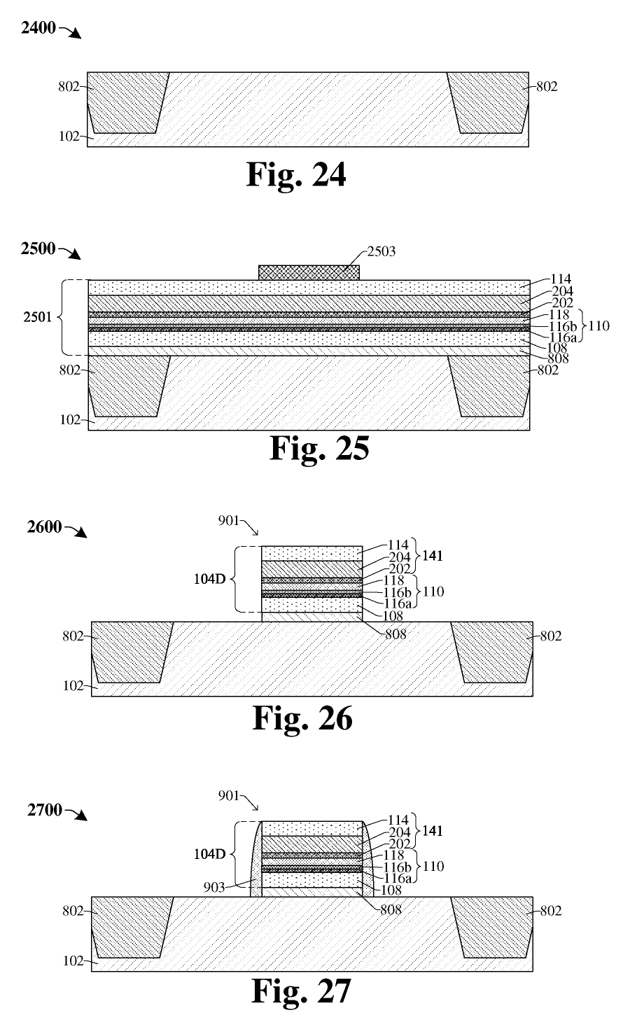

As shown in cross-sectional view 2500 of FIG. 25, a flash memory cell stack 2501 is formed over the substrate 102. The flash memory cell stack 2501 includes the gate dielectric layer 808, the bottom electrode 108, the lower oxygen affinity switching layer 116, the higher oxygen affinity switching layer 118, the diffusion barrier layer 202, which is optional, the capping metal layer 204, and the upper metal layer 114, which is also optional. The layers of the flash memory cell stack 2501 may be formed by CVD, PVD, ALD, electroplating, electroless plating, the like, or any other suitable growth or deposition process(es).

In some embodiments, the lower oxygen affinity switching layer 116 and the higher oxygen affinity switching layer 118 are formed by ALD. In some embodiments, the lower oxygen affinity switching layer 116 includes a bulk metal oxide and a dopant metal oxide and the dopant metal oxide is deposited in distinct ALD cycles from the bulk metal oxide. In some embodiments, a ratio between bulk metal oxide deposition cycles and dopant metal oxide deposition cycles is greater when depositing the sublayer 116b than when deposition the sublayer 116a. A masking layer 2503 is formed and patterned over the flash memory cell stack 2501.

As shown in cross-sectional view 2600 of FIG. 26, an etch process may be performed to pattern the flash memory cell stack 2501 (see FIG. 25) according to the masking layer 2503, thereby defining the flash memory cell 901 including the RRAM cell 104D from the flash memory cell stack 2501. The etching process may comprise, for example, one or more dry etching processes, wet etching processes, a combination thereof, or the like. The masking layer 2503 (see FIG. 25) may be removed during or after the patterning process.

As shown in cross-sectional view 2700 of FIG. 27, the spacer 903 may be formed around the flash memory cell 901. The spacer formation process may include deposition of a spacer material followed by anisotropic etching. An ion implantation process may then be carried out to form first and second source/drain regions 804a and 804b (see FIG. 9) by doping the substrate 102 in alignment with the spacer 903.

In some embodiments, the order of the RRAM cell layers in the flash memory cell stack 2501 (see FIG. 25) is reversed so that the top electrode 141 (see FIG. 27) is beneath the resistive switching structure 110, the sublayer 116a is deposited after the sublayer 116b, and the sublayer 116b is deposited after the higher oxygen affinity switching layer 118.

In some embodiments, the process of FIGS. 24-27 is modified to provide a gate replacement process. In the gate replacement process a dummy gate stack is initially formed and patterned. After the spacer 903 is formed, a dielectric layer is deposited, and the surface planarized followed by removal of the dummy gate. The flash memory cell stack 2501 is deposited so as to fill the opening left by removal of the dummy gate. After planarization, a flash memory cell with a resistive switching structure with a curved central region similar to the resistive switching structure 110C of FIG. 5 remains.

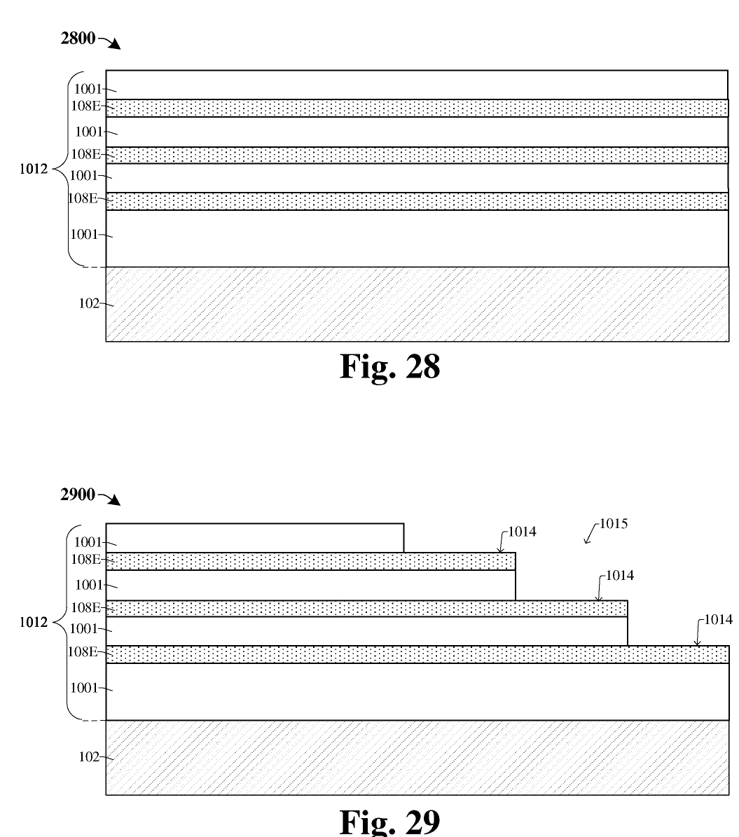

FIGS. 28-32 illustrate a series of cross-sectional views 2400-2700 of an integrated chip according to the present disclosure at various stages of a manufacturing by a process according to some embodiments. Although FIGS. 28-32 are described in relation to a series of acts, it will be appreciated that the order of the acts may in some cases be altered and that this series of acts are applicable to structures other than the ones illustrated. In some embodiments, some of these acts may be omitted in whole or in part. Furthermore, it will be appreciated that the structures shown in FIGS. 28-32 are not limited to a method of manufacture but rather may stand alone as structures separate from the method. The process is illustrated as forming the integrated chip 1000 of FIG. 10A but may be applied to manufacturing other integrated chips according to the present disclosure.

As shown in cross-sectional view 2800 of FIG. 28, the process may begin with forming the stack 1012 over the substrate 102. The stack 1012 is formed by alternating processes of depositing the dielectric layers 1001 and processes of depositing the bottom electrodes 108E. The dielectric layers 1001 may be deposited by CVD, PVD, ALD, the like, or any other suitable growth or deposition process. The bottom electrodes 108E may be formed by CVD, PVD, ALD, electroplating, electroless plating the like, or any other suitable growth or deposition process. In some embodiments, sacrificial layers are initially provided in place of the bottom electrodes 108E. The sacrificial layers may subsequently be replaced with the bottom electrodes 108E.

As shown in cross-sectional view 2900 of FIG. 29, the staircase pattern 1015 may then be formed on one side of the stack 1012. Forming the staircase pattern 1015 may comprise a plurality of masking and etching operations.

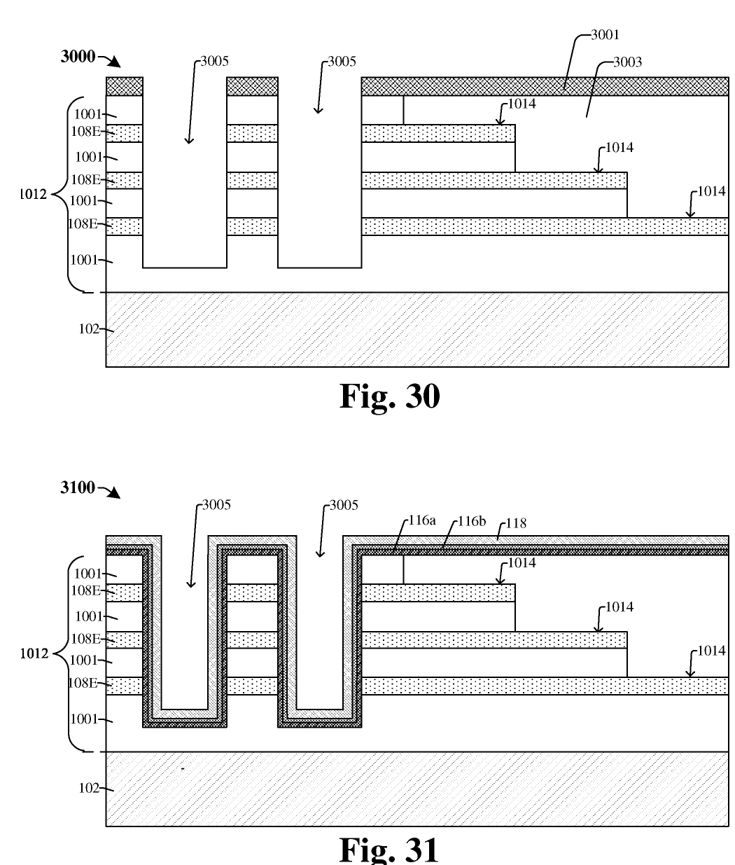

As shown in cross-sectional view 3000 of FIG. 30, a mask 3001 may be formed and used to etch holes 3005 that extend through the bottom electrodes 108E of the stack 1012. The etching process may comprise, for example, one or more processes of dry etching, wet etching, or the like. Prior to forming the mask 3001, the dielectric 3003 may be deposited and planarized to facilitate forming and patterning the mask 3001. Optionally, after etching any remaining portion of the mask 3001 may be stripped.

As shown in cross-sectional view 3100 of FIG. 31, the lower oxygen affinity switching layer 116 and the higher oxygen affinity switching layer 118 are deposited by a conformal deposition process so as to line the holes 3005. In some embodiments, the conformal deposition process is ALD or the like. In some embodiments, the lower oxygen affinity switching layer 116 includes a bulk metal oxide and a dopant metal oxide and the dopant metal oxide is deposited in distinct ALD cycles from the bulk metal oxide. In some embodiments, a ratio between bulk metal oxide deposition cycles and dopant metal oxide deposition cycles is greater when depositing the sublayer 116b than when deposition the sublayer 116a.

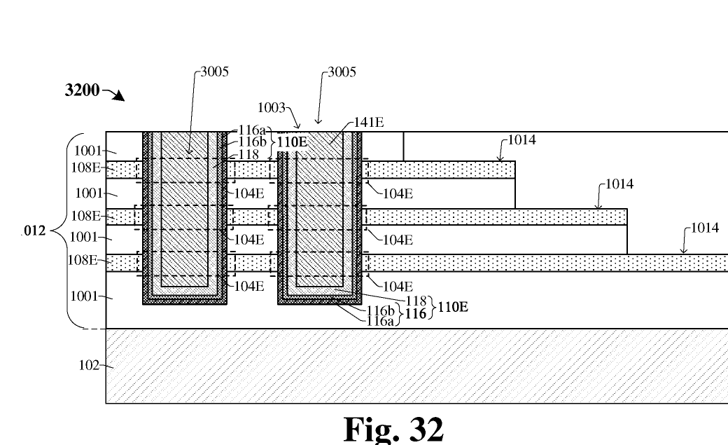

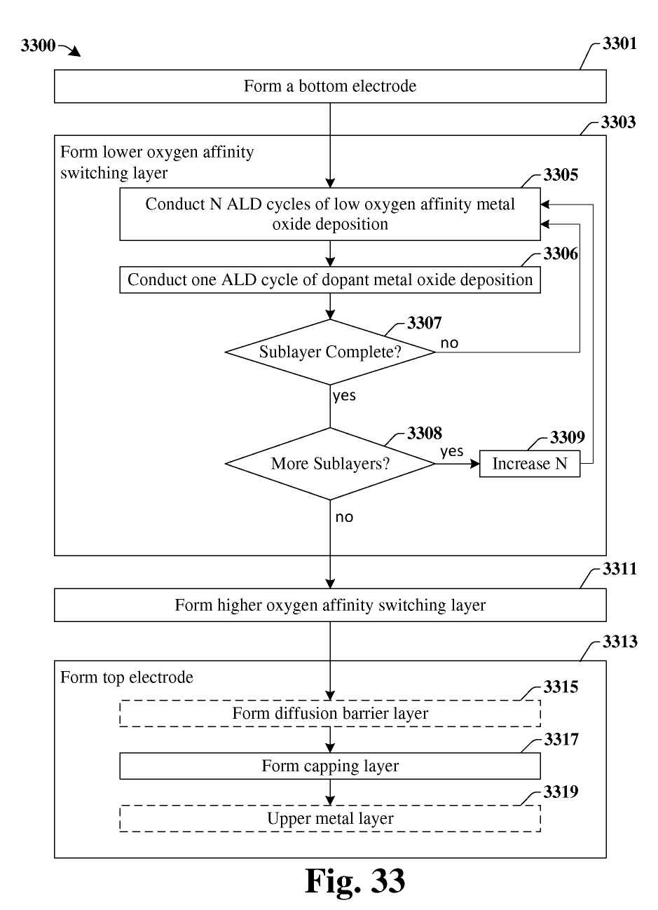

As shown in cross-sectional view 3200 of FIG. 32, the material of the top electrodes 141E may be deposited so as to fill the holes 3005 followed by planarization to confine the top electrodes 141E to the holes 3005. The top electrodes 141E may include multiple layers of various materials as shown in other examples. The top electrodes 141E may be deposited by one or more processes of CVD, PVD, ALD, electroplating, electroless plating the like, or any other suitable growth or deposition processes. The planarization process may be CMP or the like. An inter-metal dielectric layer 1013 may be deposited followed by formation of the vias 1005 and 1009 and the wires 1007 and 1011 to provide a structure as illustrated in FIGS. 10A.

FIGS. 33-36 provide flow charts for methods 3300-3600 of forming RRAM cells having resistive switching structures according to some embodiments, and of forming integrated chips including the RRAM cells. Although the methods 3300-3600 are illustrated and/or described as series of acts or events, it will be appreciated that these methods are not limited to the illustrated orderings or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

FIG. 33 provides a flow chart for a method 3300 of forming an RRAM cell having a resistive switching structure according to some embodiments. The method 3300 begins with act 3301, forming a bottom electrode. In some embodiments, the bottom electrode is selected to have a low oxygen solubility and a good work function match with the lower oxygen affinity switching layer.

Act 3303 is forming the lower oxygen affinity switching layer and includes acts 3305-3309. Act 3305 is N cycles of ALD in which monolayers of an oxide of the lower oxygen affinity metal (the bulk metal of the lower oxygen affinity switching layer) are deposited. N is initially a number that is four or greater. In some embodiments, N is initially six or greater. Act 3306 is one ALD cycle in which the oxide of a dopant metal is deposited. The dopant metal has a higher oxygen affinity than the bulk metal.

Act 3307 is determining whether deposition of a sublayer of the lower oxygen affinity switching layer has been completed. The measure of completeness may relate to a predetermined number of ALD cycles being completed, or a predetermined thickness of metal oxides having been deposited. Act 3307 causes acts 3305 and 3306 to repeat until the current sublayer deposition is complete.

When the current sublayer deposition is complete, the method 3300 continues with act 3308, determining whether there are more sublayers to deposit. If there are more sublayers to deposit, the method 3300 continues with act 3309, increasing N. The process then repeats acts 3305 and 3306 until the next sublayer deposition is complete. Increasing N causes the dopant concentration to diminish and the number of monolayers of bulk metal oxide between dopant metal oxide-containing strata to increase progressively with each succeeding sublayer.

The amount by which N is increased may vary over the course of depositing multiple sublayers. In some embodiments, the increases in N are in the range from 1 to 4. In some embodiments, the increases in N are in the range from 1 to 2. In some embodiments, N is increased by only one each time act 3309 is executed. Smaller increases in N produce smoother transitions, but N may be increased by larger amounts to achieve a desired concentration variation within the limited number of atomic layers that comprise the lower oxygen affinity switching layer.

After depositing the lower oxygen affinity switching layer, the method 3300 continues with act 3311, depositing the higher oxygen affinity switching layer. In some embodiments, this comprises a plurality of ALD cycles in which monolayers of the higher oxygen affinity metal oxide are deposited.

Act 3313 is forming a top electrode. Forming the top electrode may include act 3315, depositing a diffusion barrier layer, act 3317, depositing a capping layer, and act 3319, depositing an upper metal layer. These layers may be deposited by CVD, PVD, ALD, electroplating, electroless plating the like, or any other suitable growth or deposition processes. The capping layer is a metal with high oxygen solubility. Acts 3315 and 3319 are optional. In some embodiments, the order of steps in the method 3300 is reversed so that the layers of the RRAM cell are formed in reverse order.

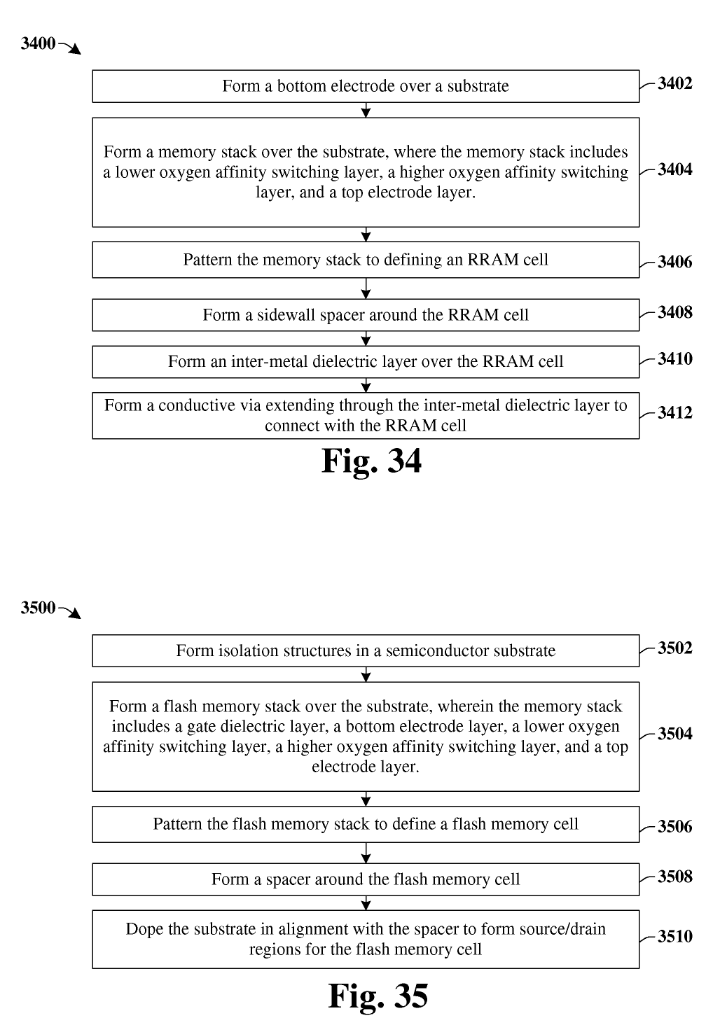

FIG. 34 provides a flow chart for a method 3400 of forming an integrated chip having an RRAM cell according to some embodiments. The method 3400 begins with act 3402, forming a bottom electrode over a substrate. The cross-sectional views 1100 and 1800 of FIGS. 11 and 18 provide examples.

Act 3404 is forming a memory stack over the substrate. The memory stack includes a lower oxygen affinity switching layer, a higher oxygen affinity switching layer, and a top electrode layer. The cross-sectional views 1200 and 1900 of FIGS. 12 and 19 provide examples. Acts 3402 and 3404 may be carried out according to the method 3300 of FIG. 33.

Act 3406 is patterning the stack memory stack to define one or more RRAM cells. The cross-sectional views 1300 and 2000 of FIGS. 13 and 20 provide examples.

Act 3408 is forming a sidewall spacer structure around, and optionally over, the RRAM cell. The cross-sectional views 1400 and 2100 of FIGS. 14 and 21 provide examples.

Act 3410 is forming an inter-metal dielectric layer over the RRAM cell. Act 3412 is forming a conductive via through the inter-metal dielectric to contact the RRAM cell. The cross-sectional views 1500 and 2200 of FIGS. 15 and 22 provide examples.

FIG. 35 provides a flow chart for a method 3500 of forming an integrated chip having a flash memory cell that incorporates an RRAM cell structure. The method 3500 begins with act 3502, forming isolation structures in the semiconductor substrate. The cross-sectional view 2400 of FIG. 24 provides an example.

Act 3504 is forming a flash memory stack over the substrate. The cross-sectional view 2500 of FIG. 25 provides an example. The flash memory stack includes a gate dielectric layer, a bottom electrode layer, a lower oxygen affinity switching layer, a higher oxygen affinity switching layer, and a top electrode layer. In some embodiments, the bottom electrode layer, the lower oxygen affinity switching layer, the higher oxygen affinity switching layer, and the top electrode layer are formed according to the method 3300 of FIG. 33. In a gate replacement process, a dummy gate stack would initially be formed in place of the flash memory stack.

Act 3506 is patterning the flash memory stack to define a flash memory cell. The cross-sectional view 2600 of FIG. 26 provides an example. In a gate replacement process, this process would pattern a dummy gate from the dummy gate stack.

Act 3508 is forming a spacer around the flash memory cell. The cross-sectional view 2700 of FIG. 27 provides an example. In a gate replacement process, this spacer would form around a dummy gate.

Act 3510 is doping in alignment with the spacer to form source/drain regions for the flash memory sell. The integrated chip 900 of FIG. 9 illustrates this type of doping. In a gate replacement process, the dummy gate would be removed, and the flash memory stack would be deposited in the resulting opening after this doping process.

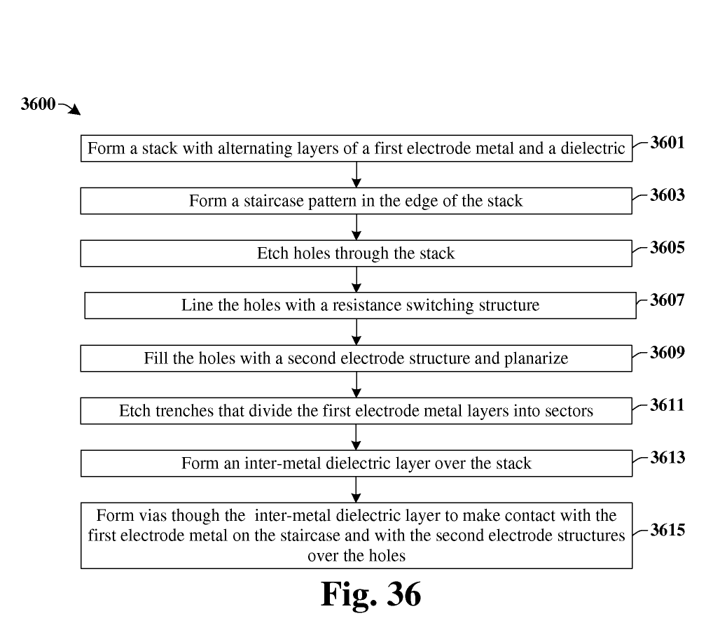

FIG. 36 provides a flow chart for a method 3600 of forming an integrated chip having a 3D array of RRAM cells. The method 3600 begins with act 3601, forming a stack having alternating layers of an electrode material and of an insulating material. The cross-sectional view 2800 of FIG. 28 provides an example.

Act 3603 is forming a staircase pattern in an edge of the stack. The staircase pattern is one in which each electrode layer is made to jut out from beneath the overlying electrode layers in a staggered arrangement. The cross-sectional view 2900 of FIG. 29 provides an example.

Act 3605 is etching arrays of holes through the stack. The cross-sectional view 3000 of FIG. 30 provides an example.

Act 3607 is lining the sides of the holes with a resistive switching structure. In some embodiments, the resistive switching structure comprises a lower oxygen affinity layer and a higher oxygen affinity layer. In some embodiments, the lower oxygen affinity layer is formed according to act 3303 in the method 3300 of FIG. 33. The cross-sectional view 3100 of FIG. 31 provides an example of the type of structure produced by lining the sides of the holes with the resistive switching structure.

Act 3609 is filling the holes with the materials of a second electrode. In some embodiments, the second electrode includes a diffusion barrier layer. In some embodiments, filling the holes includes depositing a diffusion barrier layer and a capping metal layer, wherein the capping metal is a metal with high oxygen solubility. The cross-sectional view 3200 of FIG. 32 provides an example.

Act 3611 is etching trenches through the electrode layers of the stack. These trenches are positioned to divide the electrode layers among memory cell sectors. The trenches may subsequently be filled with dielectric. The plan view 1020 of FIG. 10C illustrates example locations for these trenches.

Act 3613 is forming an inter-metal dielectric layer over the stack. Act 3615 is forming vias through the inter-metal dielectric layer. The vias include first vias the form contacts with the electrode layers of the stack and second vias that for contacts with the second electrodes that are in the holes. The cross-sectional view of the integrated chip 1000 in FIG. 10A illustrates an example of these vias.

Some aspects of the present disclosure relate to an integrated chip that includes a resistive switching structure between a first electrode and a second electrode. The resistive switching structure includes a first layer next to the first electrode and a second layer next to the second electrode. A majority of the first layer is oxides of a first metal. A minority of the first layer is oxides of a second metal. The second layer comprises oxides of a third metal. The second metal and the third metal have lower (more negative) standard Gibbs free energies of oxide formation on a per mole oxygen basis than the first metal. The first layer includes a first sublayer and a second sublayer. Both the first sublayer and the second sublayer comprise the second metal. The second sublayer has a lower concentration of the second metal than the first sublayer. The second sublayer is between the first sublayer and the second layer.

In some embodiments, a concentration of the second metal in the second sublayer is from 50% to 80% a concentration of the second metal in the first sublayer. In some embodiments, each of the first and second sublayer is from 1/3 to 2/3 the overall thickness of the first layer.

In some embodiments, the first layer also has a third sublayer, the third sublayer comprises the second metal, and the third sublayer is between the second sublayer and the second layer, and the third sublayer has a lower concentration of the second metal than the second sublayer. In some embodiments, a concentration of the second metal in the third sublayer is from 40% to 80% a concentration of the second metal in the first sublayer, and a concentration of the second metal in the second sublayer is from 70% to 95% the concentration of the second metal in the first sublayer. In some embodiments, the first, second, and third sublayers are each from 1/4 to 1/2 a thickness of the first layer.

In some embodiments, a difference in oxygen affinity between the first layer and the second layer increases a concentration of intrinsic oxygen vacancies in the first layer to an extent that lowers a forming voltage for a memory cell comprising the first electrode, the second electrode, and the resistive switching structure. In some embodiments, a content of the second metal in the first layer is in the range from 0.1% to 10% on an atomic basis. In some embodiments, the second metal has a standard Gibbs free energy of oxide formation on a per mole oxygen (O₂) basis that is at least 200 kJ/mol less than that of the first metal. In some embodiments, the third metal has a standard Gibbs free energy of oxide formation on a per mole oxygen (O₂) basis that is at least 200 kJ/mol less than that of the first metal. In some embodiments, the second metal has a standard Gibbs free energy of oxide formation on a per mole oxygen (O₂) basis that is higher than that of the third metal. In some embodiments, a thickness of the first layer is in the range from 0.5 to 1.3 a thickness of the second layer. In some embodiments, the second metal in the first layer reduces a width in the first layer of a conductive filament that forms through the resistive switching structure by pulsing a voltage difference between the first electrode and the second electrode. In some embodiments, the second electrode has a greater oxygen ion solubility than the first electrode.

In some embodiments, the second layer comprises zirconium oxide and the first layer comprises hafnium tantalum oxide, aluminum tantalum oxide, lanthanum tantalum oxide, titanium tantalum oxide, titanium silicon oxide, hafnium silicon oxide, or hafnium zinc oxide. In some embodiments, the second layer comprises hafnium oxide and the first layer comprises zirconium tantalum oxide, lanthanum tantalum oxide, titanium tantalum oxide, zirconium silicon oxide, or zirconium zinc oxide. In some embodiments, wherein the second layer comprises lanthanum oxide and the first layer comprises hafnium tantalum oxide, aluminum tantalum oxide, hafnium silicon oxide, hafnium zinc oxide, or zirconium zinc oxide.

In some embodiments, the resistive switching structure is non-planar. In some embodiments, the resistive switching structure is a data storage structure for a memory cell in a three-dimensional array of memory cells. In some embodiments, the integrated chip further comprising a gate dielectric layer between the first electrode and a semiconductor channel of a transistor, whereby the second electrode provides a gate electrode for the transistor, the first electrode is a floating gate within the transistor, and the resistive switching structure provides the transistor with a variable threshold voltage. In some embodiments, the first layer has a sub-stoichiometric amount of oxygen with respect to maximum oxides of its metal constituents.

Some aspects of the present disclosure relate to an integrated chip that includes a resistive switching structure between a first electrode and a second electrode. The resistive switching structure includes a first layer next to the first electrode and a second layer next to the second electrode. A majority of the first layer is oxides of a first metal. A minority of the first layer is oxides of a second metal. The second layer comprises oxides of a third metal. The second metal and the third metal have lower oxygen affinities than the first metal. The first layer includes a first sublayer and a second sublayer. The second sublayer is between the first sublayer and the second layer. The second metal is confined within strata within the first sublayer and the second sublayer. The strata are more widely spaced in the second sublayer than in the first sublayer.

In some embodiments, an atomic ratio between the first metal and the second metal in the first sublayer is 5:1 or greater. In some embodiments, an atomic ratio between the first metal and the second metal in the second sublayer is no more than twice the atomic ratio between the first metal and the second metal in the first sublayer. In some embodiments, the first layer further comprises a third sublayer, the second metal is confined within strata within the third sublayer, the third sublayer is between the second sublayer and the second layer, and the strata are more widely spaced in the third sublayer than in the second sublayer.

Some aspects of the present disclosure relate to a method of manufacturing an integrated chip. The method includes forming a first electrode over a substrate and depositing a first metal oxide layer, wherein the first metal oxide layer comprises a first metal and a second metal, and an atomic ratio between the first metal and the second metal in the first metal oxide layer is 5:1 or greater, and the first metal has a lower standard Gibbs free energy of oxygen vacancy formation for its maximum oxide than does the second metal. The method further includes depositing a second metal oxide layer, wherein the second metal oxide layer comprises a third metal, and the first metal has a lower standard Gibbs free energy of oxygen vacancy formation for its maximum oxide than does the third metal and forming a second electrode, wherein the first metal oxide layer and the second metal oxide layer are between the first electrode and the second electrode, and the first electrode, the first metal oxide layer, the second metal oxide layer, and the second electrode form a resistive random-access memory cell. Depositing the first metal oxide layer comprises atomic layer deposition in which oxides of the first metal and oxides of the second metal are deposited in distinct cycles. A plurality of cycles of depositing oxides of the first metal are performed between successive cycles depositing oxides of the second metal. A number of cycles of depositing oxides of the first metal between successive cycles depositing oxides of the second metal increases as the first metal oxide layer is being deposited.

In some embodiments, the number of cycles of depositing oxides of the first metal between successive cycles depositing oxides of the second metal increases at least two separate times over a course of depositing the first metal oxide layer. In some embodiments, the method further includes depositing a gate dielectric layer over a semiconductor, wherein the semiconductor is either the substrate or a structure formed over the substrate, and the first electrode is formed over the gate dielectric layer. In some embodiments, the method further includes depositing a dielectric layer over the substrate and etching an opening in the dielectric layer. Portions of the first dielectric layer and the second dielectric layer deposit within the opening.

In some embodiments, forming the first electrode over the substrate comprises depositing a stack with layers of conductive material alternating with layers of dielectric material, and the first electrode is provided by one of the layers of conductive material. In some embodiments, the method further comprising etching a hole through the stack, wherein the first metal oxide layer and the second metal oxide layer are deposited so as to line sidewalls of the hole.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a metal interconnect structure over a semiconductor substrate, wherein the metal interconnect structure comprises first and second conductive traces;
a first electrode and a second electrode disposed within the metal interconnect structure, wherein the first electrode and the second electrode are electrically coupled to the first and second conductive traces respectively; a switching structure between the first electrode and the second electrode, wherein:
the switching structure comprises a first layer proximate the first electrode and a second layer proximate the second electrode;
a majority of the first layer is oxides of a first metal, and a minority of the first layer is oxides of a second metal;
the second layer comprises oxides of a third metal; and
the second metal and the third metal have lower (more negative) standard Gibbs free energies of oxide formation on a per mole oxygen basis than the first metal;
wherein the first layer comprises a first sublayer and a second sublayer;
both the first sublayer and the second sublayer comprise the second metal;
the second sublayer has a lower concentration of the second metal than the first sublayer; and
the second sublayer is between the first sublayer and the second layer.

2. The integrated chip of claim 1, wherein a concentration of the second metal in the second sublayer is from 50% to 80% a concentration of the second metal in the first sublayer.

3. The integrated chip of claim 2, wherein:
the first layer has a first thickness;
the first sublayer is from 1/3 to 2/3 of the first thickness; and
the second sublayer is from 1/3 to 2/3 of the first thickness.

4. The integrated chip of claim 1, wherein:
the first layer comprises a third sublayer;
the third sublayer comprises the second metal;
the third sublayer is between the second sublayer and the second layer; and
the third sublayer has a lower concentration of the second metal than the second sublayer.

5. The integrated chip of claim 4, wherein:
a concentration of the second metal in the third sublayer is from 40% to 80% a concentration of the second metal in the first sublayer; and
a concentration of the second metal in the second sublayer is from 70% to 95% the concentration of the second metal in the first sublayer.

6. The integrated chip of claim 5, wherein
the first layer has a first thickness;
the first sublayer is from 1/4 to 1/2 of the first thickness;
the second sublayer is from 1/4 to 1/2 of the first thickness; and
the third sublayer is from 1/4 to 1/2 of the first thickness.

7. The integrated chip of claim 1, wherein the first sublayer has 10% or less on an atomic basis of the second metal, and the second sublayer has 0.1% or more on an atomic basis of the second metal.

8. The integrated chip of claim 1, wherein the second metal has a standard Gibbs free energy of oxide formation on a per mole oxygen (O₂) basis that is at least 200 kJ/mol less than that of the first metal.

9. The integrated chip of claim 8, wherein the third metal has a standard Gibbs free energy of oxide formation on a per mole oxygen (O₂) basis that is at least 200 kJ/mol less than that of the first metal.

10. The integrated chip of claim 1, wherein a thickness of the first layer is in the range from 0.5 to 1.3 a thickness of the second layer.

11. A method of manufacturing an integrated chip, the method comprising:
forming a metallization layer comprising a conductive trace over a substrate;
forming a stack comprising a first electrode layer, a resistive switching structure, and a second electrode layer over the metallization layer, wherein:
the first electrode layer is electrically coupled to the conductive trace;
the resistive switching structure comprises a first layer proximate the first electrode layer and a second layer proximate the second electrode layer;
a majority of the first layer is oxides of a first metal, and a minority of the first layer is oxides of a second metal;
the second layer comprises oxides of a third metal; and
the second metal and the third metal have lower oxygen affinities than the first metal; and
patterning the stack to define a resistive random access memory cell;
wherein the first layer comprises a first sublayer and a second sublayer;
the second sublayer is between the first sublayer and the second layer;
the second metal is confined within strata within the first sublayer and the second sublayer; and
the strata are more widely spaced in the second sublayer than in the first sublayer.

12. The method of claim 11, an atomic ratio between the first metal and the second metal in the first sublayer is 5:1 or greater.

13. The method of claim 12, an atomic ratio between the first metal and the second metal in the second sublayer is no more than twice the atomic ratio between the first metal and the second metal in the first sublayer.

14. The method of claim 11, wherein:
the first layer further comprises a third sublayer;
the second metal is confined within strata within the third sublayer;
the third sublayer is between the second sublayer and the second layer; and
the strata are more widely spaced in the third sublayer than in the second sublayer.

15. A method of manufacturing an integrated chip, the method comprising:
forming a first electrode over a substrate;
depositing a first metal oxide layer, wherein the first metal oxide layer comprises a first metal and a second metal, and an atomic ratio between the first metal and the second metal in the first metal oxide layer is 5:1 or greater, and the second metal has a higher standard Gibbs free energy of oxygen vacancy formation for its maximum oxide than does the first metal;
depositing a second metal oxide layer, wherein the second metal oxide layer comprises a third metal, and the third metal has a higher standard Gibbs free energy of oxygen vacancy formation for its maximum oxide than does the first metal; and
forming a second electrode, wherein the first metal oxide layer and the second metal oxide layer are between the first electrode and the second electrode, and the first electrode, the first metal oxide layer, the second metal oxide layer, and the second electrode form a resistive random-access memory cell;
wherein depositing the first metal oxide layer comprises atomic layer deposition in which oxides of the first metal and oxides of the second metal are deposited in distinct cycles;
a plurality of cycles of depositing oxides of the first metal are performed between successive cycles of depositing oxides of the second metal; and
a number of cycles of depositing oxides of the first metal between successive cycles depositing oxides of the second metal increases as the first metal oxide layer is being deposited.

16. The method of claim 15, wherein the number of cycles of depositing oxides of the first metal between successive cycles depositing oxides of the second metal increases at least two separate times over a course of depositing the first metal oxide layer.

17. The method of claim 15, wherein forming the first electrode over the substrate comprises depositing a stack with layers of conductive material alternating with layers of dielectric material, and the first electrode is provided by one of the layers of conductive material.

18. The method of claim 17, further comprising etching a hole through the stack, wherein the first metal oxide layer and the second metal oxide layer are deposited so as to line sidewalls of the hole.

19. The method of claim 15, further comprising:
depositing a dielectric layer over the substrate; and
etching an opening in the dielectric layer, wherein portions of the first metal oxide layer and the second metal oxide layer deposit within the opening.

20. The method of claim 15, further comprising depositing a gate dielectric layer over a semiconductor, wherein the semiconductor is either the substrate or a structure formed over the substrate, and the first electrode is formed over the gate dielectric layer.
